(19) United States
(12) Patent Application Publication
(10) Pub. No.: US 2024/0321958 A1
(43) Pub. Date: Sep. 26, 2024

(54) Semiconductor Devices and Methods of Designing and Forming the Same

(71) Applicant: Taiwan Semiconductor Manufacturing Co., Ltd., Hsinchu (TW)

(72) Inventors: Yu-Lung Tung, Kaohsiung City (TW); Xiaodong Wang, Hsinchu (TW); Jhon Jhy Liaw, Zhudong Township (TW)

(21) Appl. No.: 18/187,233

(22) Filed: Mar. 21, 2023

(51) Int. Cl. H01L 29/06; H01L 21/8238; H01L 27/092; H01L 29/423; H01L 29/66; H01L 29/775; H01L 29/786

(52) U.S. Cl. CPC H01L 29/0673; H01L 21/823807; H01L 27/092; H01L 29/42392; H01L 29/66439; H01L 29/775; H01L 29/78696

(57) ABSTRACT

In an embodiment, a method includes: placing a first cell in a device layout, the first cell defining a first transistor, the first transistor including a first quantity of first nanostructures; placing a second cell in the device layout directly adjacent to the first cell, the second cell defining a second transistor, the second transistor including a second quantity of second nanostructures, the second quantity being different than the first quantity; generating a lithography mask based on the device layout; and manufacturing a semiconductor device using the lithography mask.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nanostructure-FET) in a three-dimensional view, in accordance with some embodiments.

FIGS. 2-17B are views of intermediate stages in the manufacturing of nanostructure-FETs, in accordance with some embodiments.

FIGS. 18-20 are views of intermediate stages in the manufacturing of nanostructure-FETs, in accordance with some embodiments.

FIGS. 21-23 illustrate device layouts for a semiconductor device, in accordance with some embodiments.

FIGS. 24-27 illustrate device layouts for a semiconductor device, in accordance with some other embodiments.

FIGS. 28A-28D illustrate device layouts for a semiconductor device, in accordance with some other embodiments.

FIGS. 29A-29D illustrate device layouts for a semiconductor device, in accordance with some other embodiments

FIG. 30 is a flow diagram of a method of forming a semiconductor device.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a semiconductor device is designed by placing cells in a device layout. Different types of cells (e.g., high-performance cells and high-efficiency cells) define transistors with different quantities of nanostructures. The devices defined by the cells may thus have different work functions. The cells defining devices with different quantities of nanostructures allows the performance of the defined devices to be modulated without increasing the size of the cells in the layout.

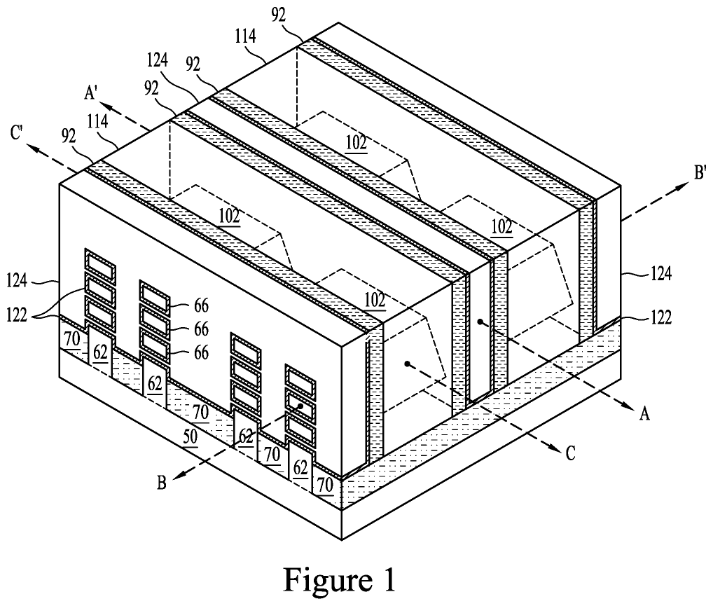

FIG. 1 illustrates an example of nanostructure-FETs (e.g., nanowire FETs, nanosheet FETs, multi bridge channel (MBC) FETs, nanoribbon FETs, gate-all-around (GAA) FETs, or the like), in accordance with some embodiments. FIG. 1 is a three-dimensional view, where some features of the nanostructure-FETs are omitted for illustration clarity.

The nanostructure-FETs include nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portion of the fins 62 and/or the substrate 50 may include a single material or a plurality of materials. In this context, the fins 62 refer to the portion extending between the neighboring isolation regions 70.

Gate dielectrics 122 are over top surfaces of the fins 62 and along top surfaces, sidewalls, and bottom surfaces of the nanostructures 66. Gate electrodes 124 are over the gate dielectrics 122. Source/drain regions 102 are disposed on the fins 62 at opposing sides of the gate dielectrics 122 and the gate electrodes 124. Source/drain region(s) 102 may refer to a source or a drain, individually or collectively dependent upon the context. An inter-layer dielectric (ILD) 114 is formed over the source/drain regions 102. Contacts (subsequently described) to the source/drain regions 102 will be formed through the ILD 114. The source/drain regions 102 may be shared between various nanostructures 66. For example, adjacent source/drain regions 102 may be electrically connected, such as through coalescing the source/drain regions 102 by epitaxial growth, or through coupling the source/drain regions 102 with a same contact.

FIG. 1 further illustrates reference cross-sections that are used in later figures. Cross-section A-A′ is along a longitudinal axis of a gate electrode 124. Cross-section B-B′ is perpendicular to cross-section A-A′ and is along a longitudinal axis of a fin 62 of a nanostructure-FET and in a direction of, for example, a current flow between the source/drain regions 102 of the nanostructure-FET. Cross-section C-C′ is perpendicular to cross-section A-A′ and extends through source/drain regions 102 of the nanostructure-FETs. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs.

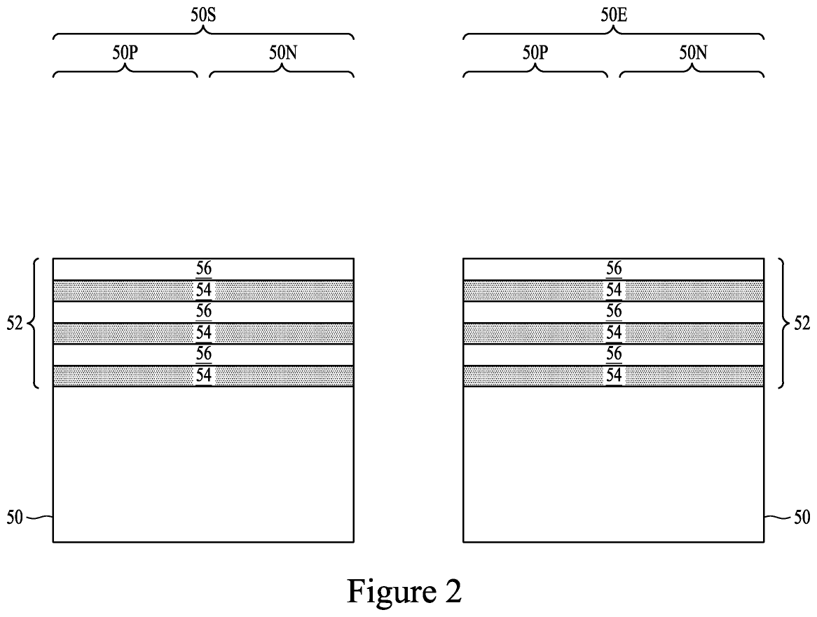

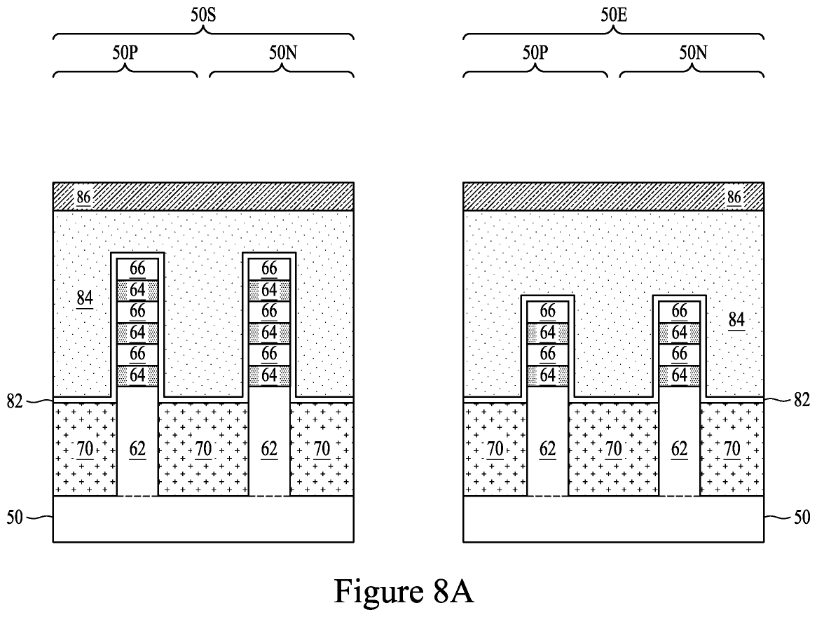

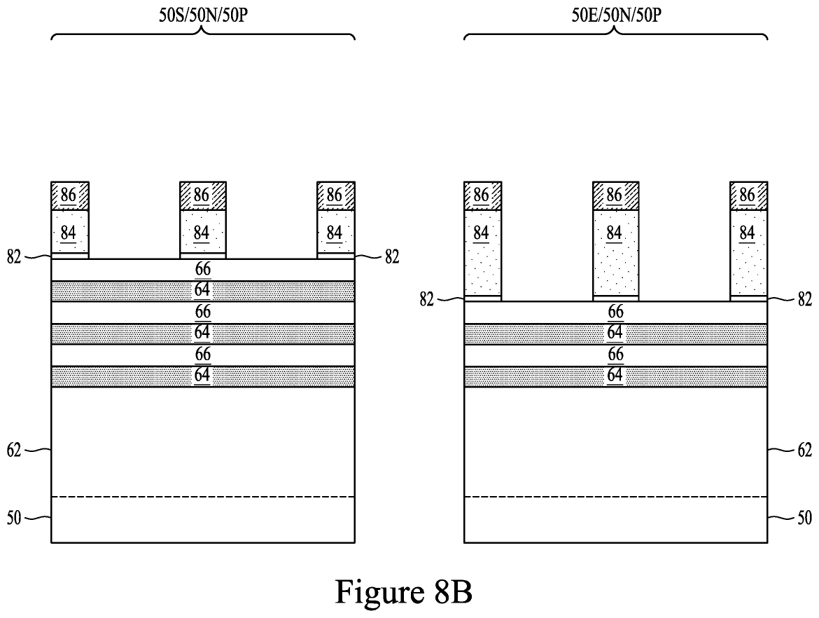

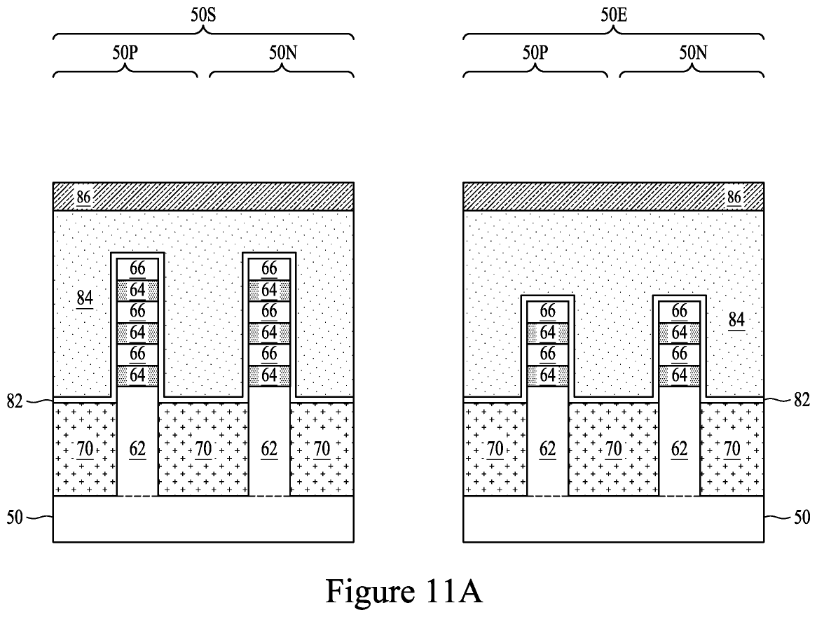

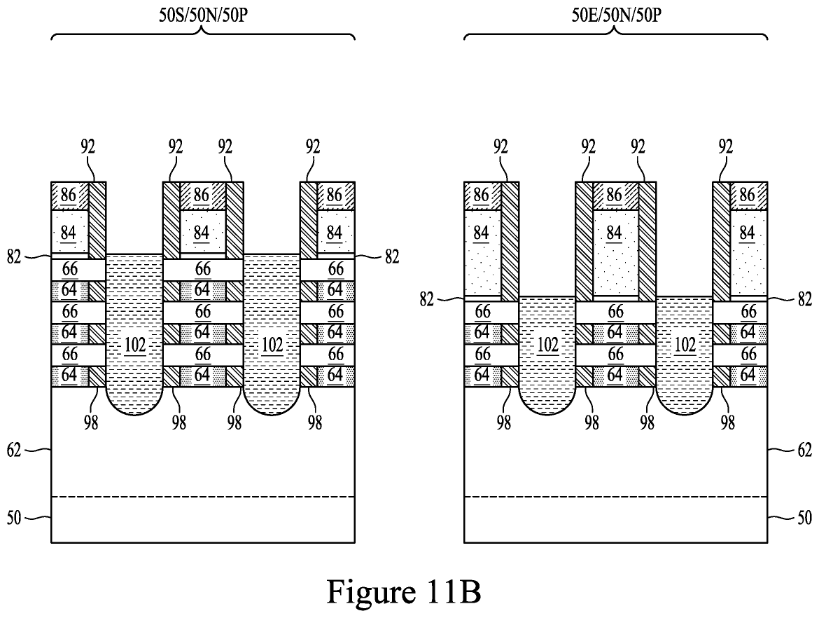

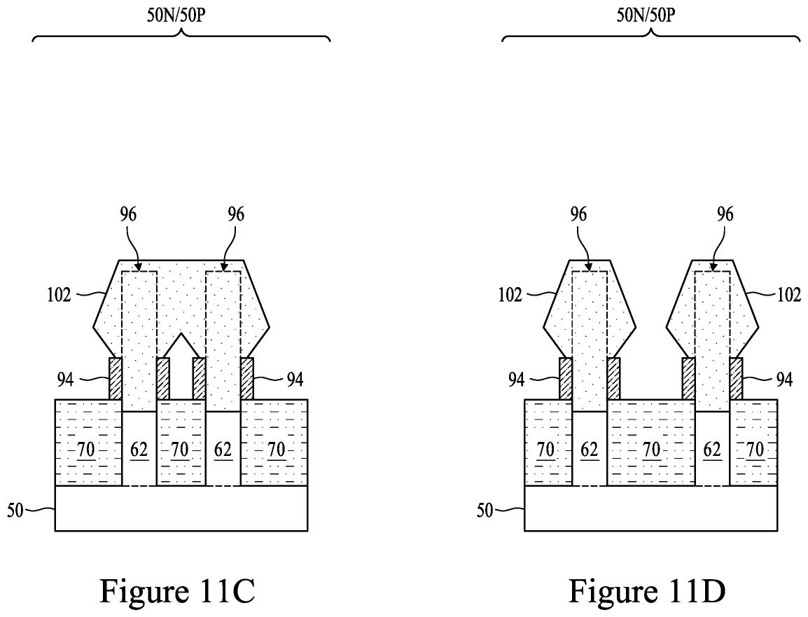

FIGS. 2-17B are views of intermediate stages in the manufacturing of nanostructure-FETs, in accordance with some embodiments. FIGS. 2, 3, 4, 5, 6, 7, 8A, 9A, 10A, 11A, 12A, 13A, 14A, 15A, 16A, and 17A illustrate cross-sectional views along a similar cross-section as reference cross-section A-A′ in FIG. 1. FIGS. 8B, 9B, 10B, 11B, 12B, 13B, 14B, 15B, 16B, and 17B illustrate cross-sectional views along a similar cross-section as reference cross-section B-B′ in FIG. 1. FIGS. 11C and 11D illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has n-type regions 50N and p-type regions 50P. The n-type regions 50N can be for forming n-type devices, such as NMOS transistors, e.g., n-type nanostructure-FETs, and the p-type regions 50P can be for forming p-type devices, such as PMOS transistors, e.g., p-type nanostructure—FETs. The n-type regions 50N may (or may not) be physically separated (not separately illustrated) from the p-type regions 50P, and any number of device features (e.g., other active devices, doped regions, isolation structures, etc.) may be disposed between the n-type regions 50N and the p-type regions 50P.

A multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50.

In the illustrated embodiment, and as subsequently described in greater detail, the first semiconductor layers 54 will be removed and the second semiconductor layers 56 will patterned to form channel regions for the nanostructure-FETs in both the n-type regions 50N and the p-type regions 50P. In such embodiments, the channel regions in both the n-type regions 50N and the p-type regions 50P may have a same material composition (e.g., silicon or another semiconductor material) and be formed simultaneously. The first semiconductor layers 54 are dummy layers that will be removed in subsequent processing to expose the top surfaces and the bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nanostructure-FETs in one type of region (e.g., the p-type regions 50P), and the second semiconductor layers 56 will be patterned to form channel regions for nanostructure-FETs in another type of region (e.g., the n-type regions 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type regions 50N, and the second semiconductor layers 56 may be removed without significantly removing the first semiconductor layers 54 in the p-type regions 50P.

In the illustrated example, the multi-layer stack 52 includes three of the first semiconductor layers 54 and three of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 are formed to be thinner than other layers of the multi-layer stack 52.

A high-efficiency region 50E and a high-speed region 50S are illustrated. As subsequently described in greater detail, some layers of the multi-layer stack 52 will be removed from the high-efficiency region 50E. Accordingly, the devices formed in the high-speed region 50S have more channel regions than the devices formed in the high-efficiency region 50E. As a result, the devices in the high-speed region 50S will have a larger effective work function than the devices in the high-efficiency region 50E. Therefore, the devices formed in the high-speed region 50S have greater performance than the devices formed in the high-efficiency region 50E, and the devices formed in the high-efficiency region 50E have greater power efficiency than the devices formed in the high-speed region 50S. Each of the high-efficiency region 50E and the high-speed region 50S can include devices from both of the n-type regions 50N and the p-type regions 50P. In other words, the high-efficiency region 50E and the high-speed region 50S can each include n-type devices and p-type devices.

As subsequently described in greater detail, the high-efficiency region 50E and the high-speed region 50S may each be defined by different cells of a device layout for a semiconductor device. Multiple cells will be placed in the device layout during a design process. One or more lithography mask(s) will be formed based on the device layout. A semiconductor device will be manufactured using the lithography mask(s).

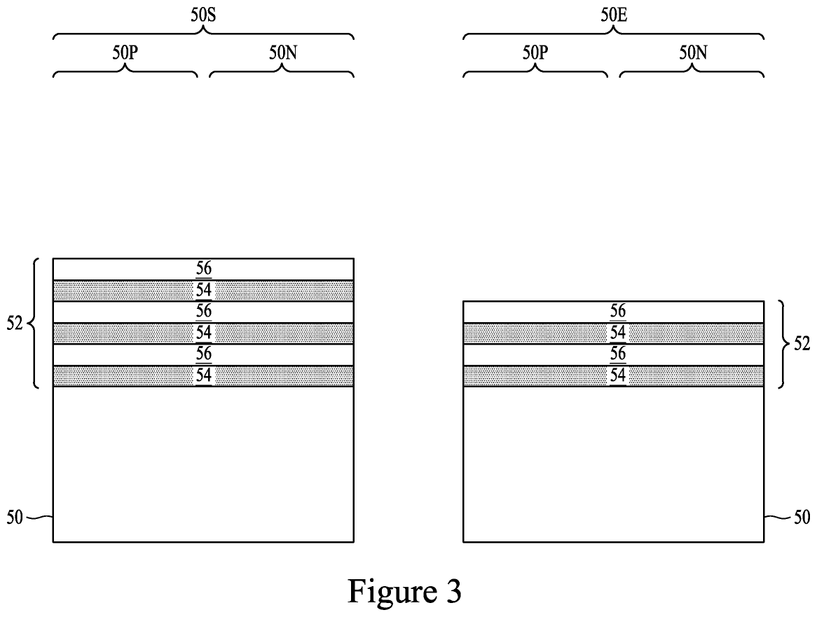

In FIG. 3, some layers of the multi-layer stack 52 are removed from the high-efficiency region 50E. Accordingly, the multi-layer stack 52 has more layers in the high-speed region 50S than in the high-efficiency region 50E. The desired layers of the multi-layer stack 52 may be removed using acceptable photolithography and etching techniques. A lithography mask generated from a device layout (subsequently described) may be used as an etching mask when removing the layers of the multi-layer stack 52 from desired regions. In the illustrated example, one of the 54 first semiconductor layers 54 and one of the second semiconductor layers 56 are removed from the high-efficiency region 50E. It should be appreciated that any number of the first semiconductor layers 54 and the second semiconductor layers 56 may be removed from the high-efficiency region 50E.

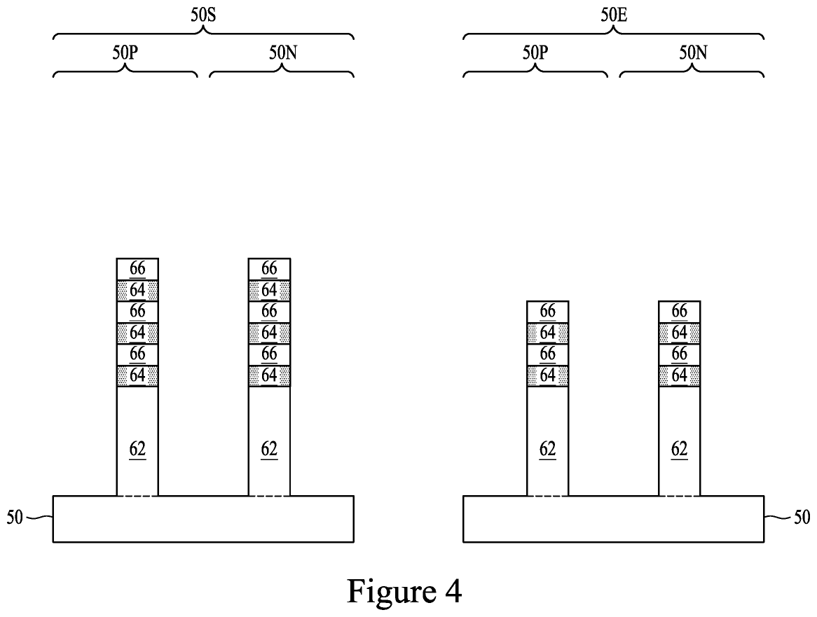

In FIG. 4, fins 62 are formed in the substrate 50 and nanostructures 64, 66 are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. A lithography mask generated from a device layout (subsequently described) may be used as an etching mask when etching the trenches in the multi-layer stack 52. Forming the nanostructures 64, 66 by etching the multi-layer stack 52 may further define first nanostructures 64 from the first semiconductor layers 54 and define second nanostructures 66 from the second semiconductor layers 56.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66.

The nanostructures 64, 66 are illustrated as having substantially equal widths in both the n-type regions 50N and the p-type regions 50P. In some embodiments, the widths of the nanostructures 64, 66 in the n-type regions 50N may be greater or less than the width of the nanostructures 64, 66 in the p-type regions 50P. The nanostructures 64, 66 in the n-type regions 50N may have the same thickness as the nanostructures 64, 66 in the p-type regions 50P. Further, while each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in shape.

Due to the patterning of the multi-layer stack 52 (previously described), the devices (e.g., transistors) in the high-speed region 50S will include more channel regions than the devices in the high-efficiency region 50E. The nanostructures 64, 66 are illustrated as having substantially equal widths in both the high-speed region 50S and the high-efficiency region 50E. In some embodiments, the widths of the nanostructures 64, 66 in the high-speed region 50S may be greater or less than the width of the nanostructures 64, 66 in the high-efficiency region 50E. The nanostructures 64, 66 in the high-efficiency region 50E have the same thickness as the nanostructures 64, 66 in the high-speed region 50S.

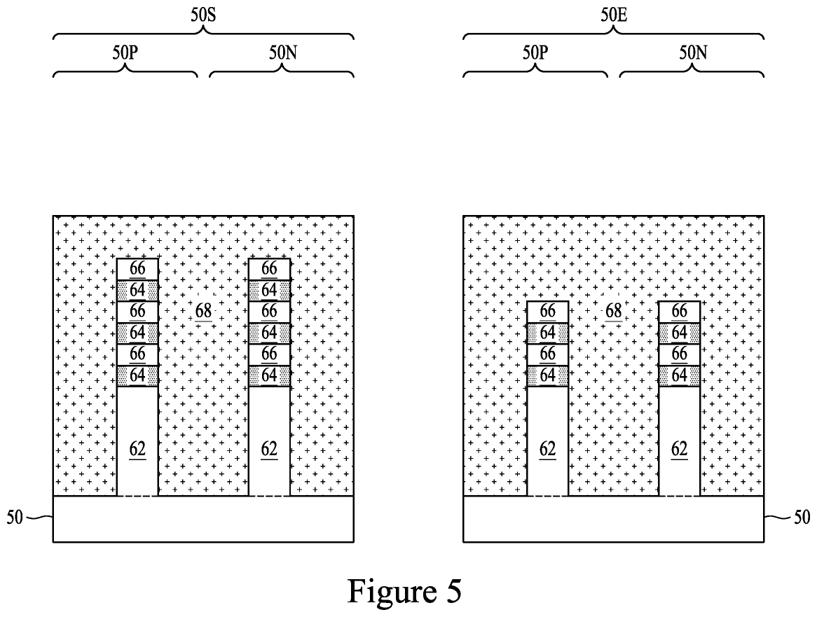

In FIG. 5, an insulation material 68 is formed over the substrate 50 and between adjacent fins 62 and adjacent nanostructures 64, 66. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, and the nanostructures 64, 66. Thereafter, a fill material, such as one of the previously described insulation materials may be formed over the liner. The insulation material 68 may be deposited over the fins 62 and nanostructures 64, 66 such that excess insulation material 68 covers the nanostructures 64, 66.

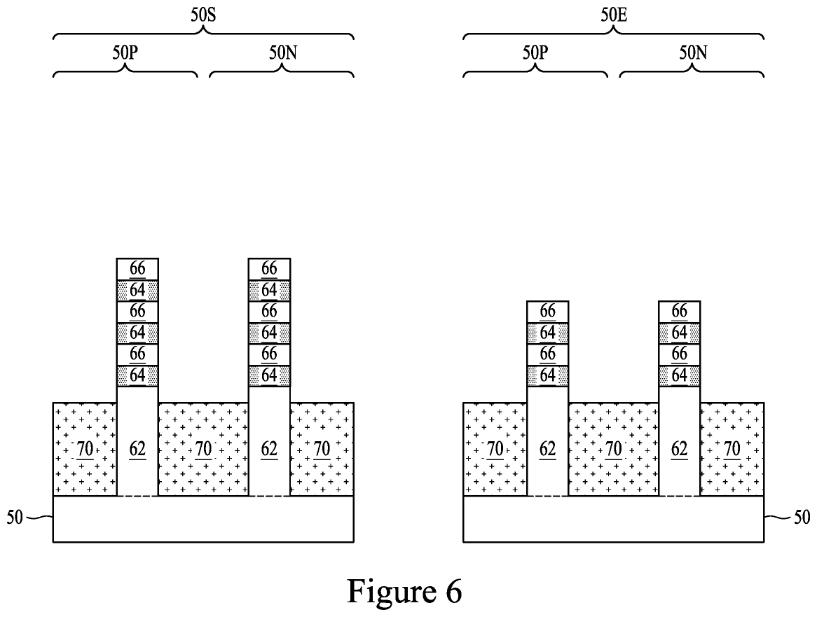

In FIG. 6, the insulation material 68 is recessed to form isolation regions 70. The isolation regions 70 are adjacent the fins 62. The insulation material 68 is recessed such that upper portions of fins 62 and/or the nanostructures 64, 66 protrude from between neighboring isolation regions 70. The upper portions of the fins 62 and/or the nanostructures 64, 66 are above the isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an acceptable etching process, such as one that is selective to the material of the insulation material 68 (e.g., etches the material of the insulation material 68 at a faster rate than the materials of the fins 62 and the nanostructures 64, 66). For example, an oxide removal using, for example, dilute hydrofluoric (dHF) acid may be used.

The previously described process is just one example of how the fins 62 and the nanostructures 64, 66 may be formed. In some embodiments, the fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64, 66. The epitaxial structures may include the previously described alternating semiconductor materials, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together. A removal process (similar to that previously described for FIG. 3) may be performed to remove some of the epitaxially grown materials from desired regions.

Further, appropriate wells (not separately illustrated) may be formed in the fins 62, the nanostructures 64, 66, and/or the isolation regions 70. In embodiments with different well types, different implant steps for the n-type regions 50N and the p-type regions 50P may be achieved using a photoresist or other mask (not separately illustrated). For example, a photoresist may be formed over the fins 62, the nanostructures 64, 66, and the isolation regions 70 in the n-type regions 50N and the p-type regions 50P. The photoresist is patterned to expose the p-type regions 50P. The photoresist can be formed by using a spin-on technique and can be patterned using acceptable photolithography techniques. Once the photoresist is patterned, an n-type impurity implant is performed in the p-type regions 50P, and the photoresist may act as a mask to substantially prevent n-type impurities from being implanted into the n-type regions 50N. The n-type impurities may be phosphorus, arsenic, antimony, or the like implanted in the region to a concentration in a range from 10¹³ atoms/cm³ to 10¹⁴ atoms/cm³. After the implant, the photoresist is removed, such as by an acceptable ashing process.

Following or prior to the implanting of the p-type regions 50P, a photoresist or other mask (not separately illustrated) is formed over the fins 62, the nanostructures 64, 66, and the isolation regions 70 in the p-type regions 50P and the n-type regions 50N. The photoresist is patterned to expose the n-type regions 50N. The photoresist can be formed by using a spin-on technique and can be patterned using acceptable photolithography techniques. Once the photoresist is patterned, a p-type impurity implant may be performed in the n-type regions 50N, and the photoresist may act as a mask to substantially prevent p-type impurities from being implanted into the p-type regions 50P. The p-type impurities may be boron, boron fluoride, indium, or the like implanted in the region to a concentration in a range from 10¹³ atoms/cm³ to 10¹⁴ atoms/cm³. After the implant, the photoresist may be removed, such as by an acceptable ashing process.

After the implants of the n-type regions 50N and the p-type regions 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

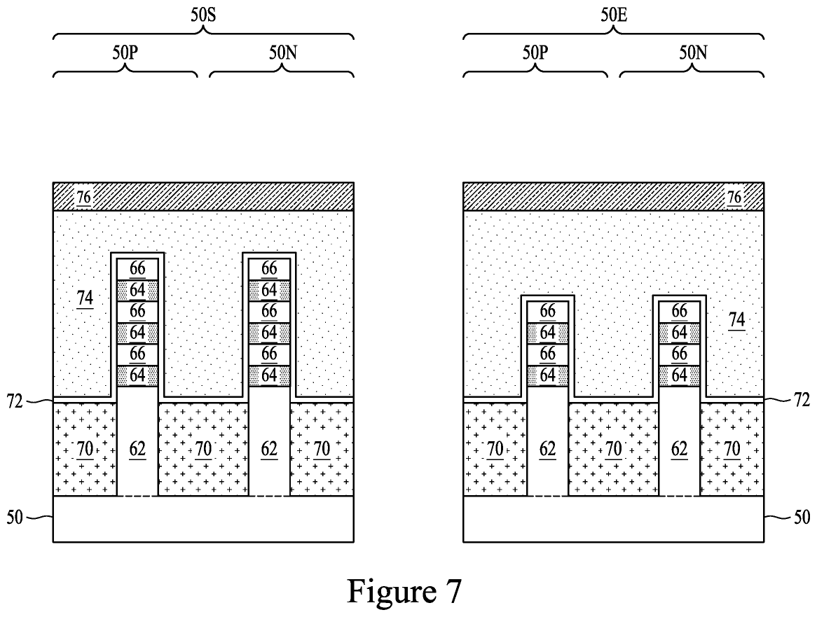

In FIG. 7, a dummy dielectric layer 72 is formed on the fins 62 and/or the nanostructures 64, 66. The dummy dielectric layer 72 may be formed of silicon oxide, silicon nitride, a combination thereof, or the like, which may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a chemical mechanical polish (CMP). The dummy gate layer 74 may be formed of a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The material of the dummy gate layer 74 may be deposited by CVD, physical vapor deposition (PVD), sputter deposition, or other techniques for depositing the selected material. The dummy gate layer 74 may be formed of other materials that have a high etching selectivity from the etching of insulation materials, e.g., the isolation regions 70 and/or the dummy dielectric layer 72. The mask layer 76 may be deposited over the dummy gate layer 74. The mask layer 76 may be formed of a dielectric material such as silicon nitride, silicon oxynitride, or the like. In this example, a single dummy gate layer 74 and a single mask layer 76 are formed across the n-type regions 50N and the p-type regions 50P. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

FIGS. 8A-17B illustrate various additional steps in the manufacturing of embodiment devices. FIGS. 8B, 9B, 10B, 11B, 11C, 11D, 12B, 13B, 14B, 15B, 16B, and 17B illustrate features in either of the n-type regions 50N and the p-type regions 50P. For example, the structures illustrated may be applicable to both the n-type regions 50N and the p-type regions 50P. Differences (if any) in the structures of the n-type regions 50N and the p-type regions 50P will be explained in the description of each figure.

In FIGS. 8A-8B, the mask layer 76 is patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. A lithography mask generated from a device layout (subsequently described) may be used as an etching mask when patterning the dummy gates 84. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

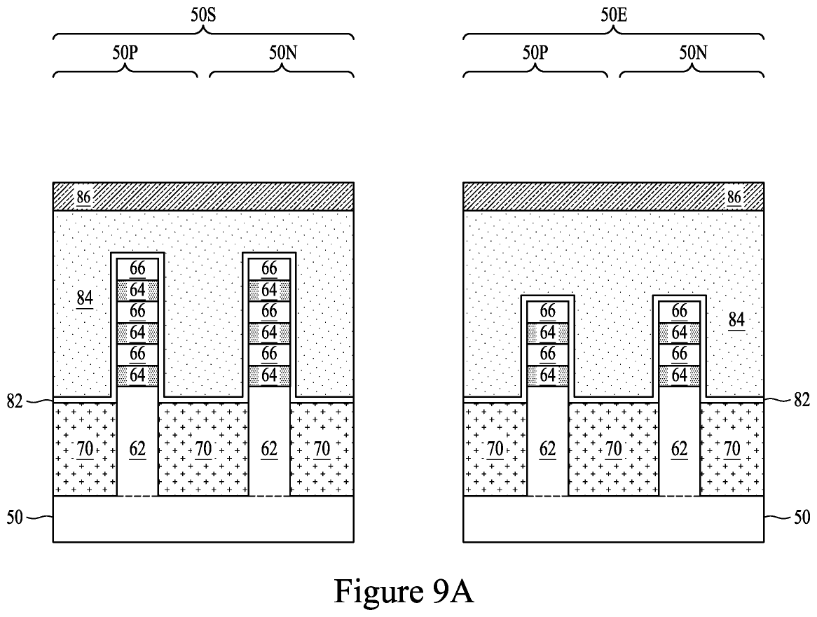

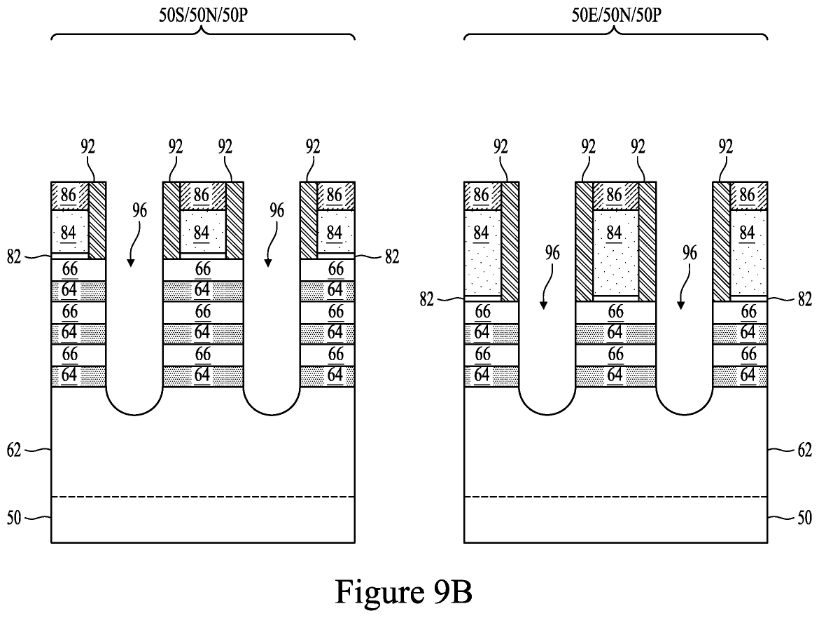

In FIGS. 9A-9B, gate spacers 92 are formed over the nanostructures 64, 66 and the isolation regions 70, on exposed sidewalls of the masks 86 (if present), the dummy gates 84, and the dummy dielectrics 82. The gate spacers 92 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 92). As will be subsequently described in greater detail, the dielectric material(s), when etched, may also have portions left on the sidewalls of the fins 62 and/or the nanostructures 64, 66 (thus forming fin spacers 94, see FIGS. 11C-11D). After etching, the fin spacers 94 and/or the gate spacers 92 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 92 are formed. In embodiments with different device types, similar to the implants for the previously described wells, a mask, such as a photoresist, may be formed over the n-type regions 50N, while exposing the p-type regions 50P, and appropriate type (e.g., p-type) impurities may be implanted into the fins 62 and the nanostructures 64, 66 exposed in the p-type regions 50P. The mask may then be removed. Subsequently, a mask, such as a photoresist, may be formed over the p-type regions 50P while exposing the n-type regions 50N, and appropriate type impurities (e.g., n-type) may be implanted into the fins 62 and the nanostructures 64, 66 exposed in the n-type regions 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Source/drain recesses 96 are patterned in the fins 62, the nanostructures 64, 66, and the substrate 50. Epitaxial source/drain regions will be subsequently formed in the source/drain recesses 96. The source/drain recesses 96 may extend through the nanostructures 64, 66 and into the substrate 50. In some embodiments, the fins 62 may be etched such that bottom surfaces of the source/drain recesses 96 are disposed below the top surfaces of the isolation regions 70. The source/drain recesses 96 may be formed by etching the fins 62, the nanostructures 64, 66, and the substrate 50 using anisotropic etching processes, such as RIE, NBE, or the like. The gate spacers 92 and the dummy gates 84 mask portions of the fins 62, the nanostructures 64, 66, and the substrate 50 during the etching processes used to form the source/drain recesses 96. A single etch process or multiple etch processes may be used to etch each layer of the nanostructures 64, 66 and/or the fins 62. Timed etch processes may be used to stop the etching of the source/drain recesses 96 after the source/drain recesses 96 reach a desired depth.

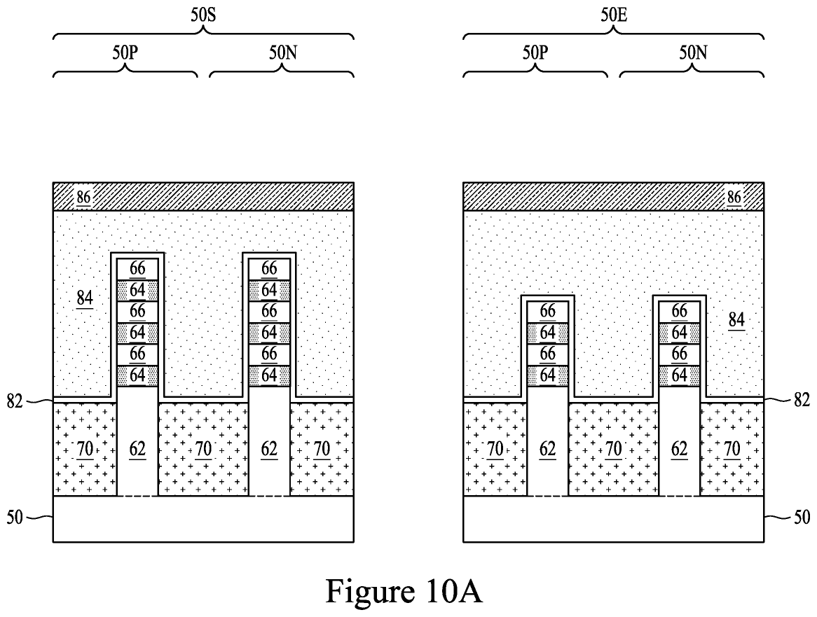

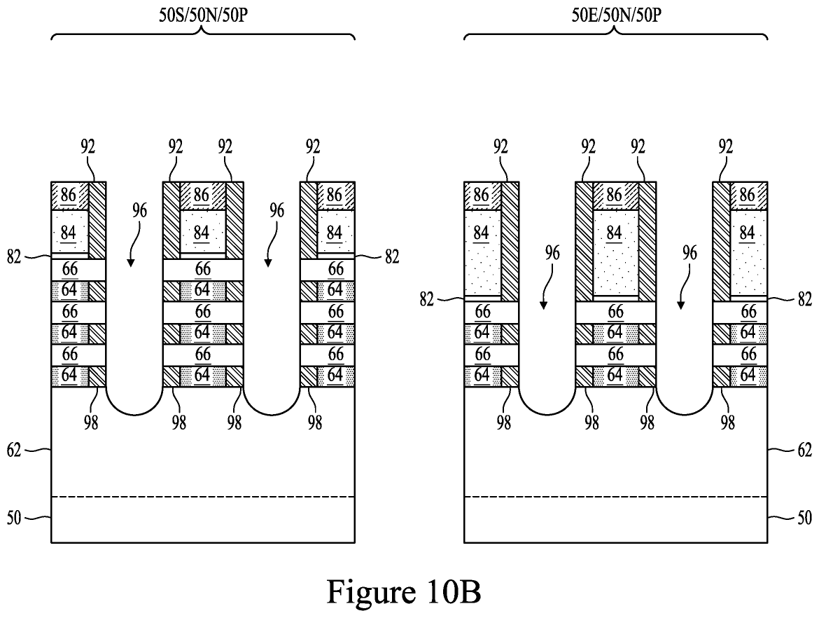

In FIGS. 10A-10B, inner spacers 98 are formed on the sidewalls of the remaining portions of the first nanostructures 64, e.g., those sidewalls exposed by the source/drain recesses 96. As will be subsequently described in greater detail, source/drain regions will be subsequently formed in the source/drain recesses 96, and the first nanostructures 64 will be subsequently replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to subsequently remove the first nanostructures 64.

As an example to form the inner spacers 98, the source/drain recesses 96 can be laterally expanded. Specifically, portions of the sidewalls of the first nanostructures 64 exposed by the source/drain recesses 96 may be recessed to form sidewall recesses. Although sidewalls of the first nanostructures 64 are illustrated as being straight, the sidewalls may be concave or convex. The sidewalls may be recessed by any acceptable etch process, such as one that is selective to the material of the first nanostructures 64 (e.g., selectively etches the material of the first nanostructures 64 at a faster rate than the material of the second nanostructures 66). The etching may be isotropic. For example, when the second nanostructures 66 are formed of silicon and the first nanostructures 64 are formed of silicon germanium, the etch process may be a wet etch using tetramethylammonium hydroxide (TMAH), ammonium hydroxide (NH₄OH), or the like. In another embodiment, the etch process may be a dry etch using a fluorine-based gas such as hydrogen fluoride (HF) gas. In some embodiments, the same etch process may be continually performed to both form the source/drain recesses 96 and recess the sidewalls of the first nanostructures 64. The inner spacers 98 can then be formed by conformally forming an insulating material in the source/drain recesses 96 (including the sidewall recesses), and subsequently etching the insulating material. The insulating material may be silicon nitride or silicon oxynitride, although any suitable material, such as low-dielectric constant (low-k) materials having a k-value less than about 3.5, may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the sidewall recesses (thus forming the inner spacers 98).

Although outer sidewalls of inner spacers 98 are illustrated as being flush with sidewalls of the second nanostructures 66, the outer sidewalls of the inner spacers 98 may extend beyond or be recessed from sidewalls of the second nanostructures 66. In other words, the inner spacers 98 may partially fill, completely fill, or overfill the sidewall recesses. Moreover, although the sidewalls of the inner spacers 98 are illustrated as being straight, the sidewalls of the inner spacers 98 may be concave or convex.

In FIGS. 11A-11B, epitaxial source/drain regions 102 are formed in the source/drain recesses 96. In some embodiments, the epitaxial source/drain regions 102 exert stress in the respective channel regions of the second nanostructures 66, thereby improving performance. The epitaxial source/drain regions 102 are formed in the source/drain recesses 96 such that each dummy gate 84 is disposed between respective neighboring pairs of the epitaxial source/drain regions 102. In some embodiments, the gate spacers 92 are used to separate the epitaxial source/drain regions 102 from the dummy gates 84 and the inner spacers 98 are used to separate the epitaxial source/drain regions 102 from the nanostructures 64 by an appropriate lateral distance so that the epitaxial source/drain regions 102 do not short out with subsequently formed gates of the resulting nanostructure-FETs.

The epitaxial source/drain regions 102 in the n-type regions 50N may be formed by masking the p-type regions 50P. Then, the epitaxial source/drain regions 102 are epitaxially grown in the source/drain recesses 96 in the n-type regions 50N. The epitaxial source/drain regions 102 may include any acceptable material appropriate for n-type nanostructure-FETs. For example, if the second nanostructures 66 are formed of silicon, the epitaxial source/drain regions 102 may include materials exerting a tensile strain on the second nanostructures 66, such as silicon, silicon carbide, phosphorous doped silicon carbide, silicon phosphide, or the like. The epitaxial source/drain regions 102 in the n-type regions 50N may be referred to as “n-type source/drain regions.” The epitaxial source/drain regions 102 may have surfaces raised from respective upper surfaces of the nanostructures 64, 66 and may have facets.

The epitaxial source/drain regions 102 in the p-type regions 50P may be formed by masking the n-type regions 50N. Then, the epitaxial source/drain regions 102 are epitaxially grown in the source/drain recesses 96 in the p-type regions 50P. The epitaxial source/drain regions 102 may include any acceptable material appropriate for p-type nanostructure-FETs. For example, if the second nanostructures 66 are formed of silicon, the epitaxial source/drain regions 102 may include materials exerting a compressive strain on the first nanostructures 64, such as silicon-germanium, boron doped silicon-germanium, germanium, germanium tin, or the like. The epitaxial source/drain regions 102 in the p-type regions 50P may be referred to as “p-type source/drain regions.” The epitaxial source/drain regions 102 may also have surfaces raised from respective surfaces of the nanostructures 64, 66 and may have facets.

The epitaxial source/drain regions 102, the nanostructures 64, 66, and/or the fins 62 may be implanted with dopants to form source/drain regions, similar to the process previously discussed for forming lightly-doped source/drain regions, followed by an anneal. The source/drain regions may have an impurity concentration of between 10¹⁹ atoms/cm³ and 10²¹ atoms/cm³. The n-type and/or p-type impurities for source/drain regions may be any of the impurities previously discussed. In some embodiments, the epitaxial source/drain regions 102 may be in situ doped during growth.

As a result of the epitaxy processes used to form the epitaxial source/drain regions 102, upper surfaces of the epitaxial source/drain regions 102 have facets which expand laterally outward beyond sidewalls of the nanostructures 64, 66. In some embodiments, these facets cause adjacent epitaxial source/drain regions 102 of a same nanostructure-FET to merge as illustrated by FIG. 11C. In other embodiments, adjacent epitaxial source/drain regions 102 remain separated after the epitaxy process is completed as illustrated by FIG. 11D. In the illustrated embodiments, the fin spacers 94 are formed on a top surface of the isolation regions 70, thereby blocking the epitaxial growth. In some other embodiments, the fin spacers 94 may cover portions of the sidewalls of the nanostructures 64, 66 and/or the fins 62, further blocking the epitaxial growth. In another embodiment, the spacer etch used to form the gate spacers 92 is adjusted to not form the fin spacers 94, so as to allow the epitaxial source/drain regions 102 to extend to the surface of the isolation regions 70.

The epitaxial source/drain regions 102 may include one or more semiconductor material layers. For example, the epitaxial source/drain regions 102 may include a first semiconductor material layer, a second semiconductor material layer, and a third semiconductor material layer. Any number of semiconductor material layers may be used for the epitaxial source/drain regions 102. Each of the first semiconductor material layer, the second semiconductor material layer, and the third semiconductor material layer may be formed of different semiconductor materials and may be doped to different dopant concentrations. In some embodiments, the first semiconductor material layer may have a dopant concentration less than the second semiconductor material layer and greater than the third semiconductor material layer. In embodiments in which the epitaxial source/drain regions 102 include three semiconductor material layers, the first semiconductor material layer may be grown, the second semiconductor material layer may be grown over the first semiconductor material layer, and the third semiconductor material layer may be grown over the second semiconductor material layer.

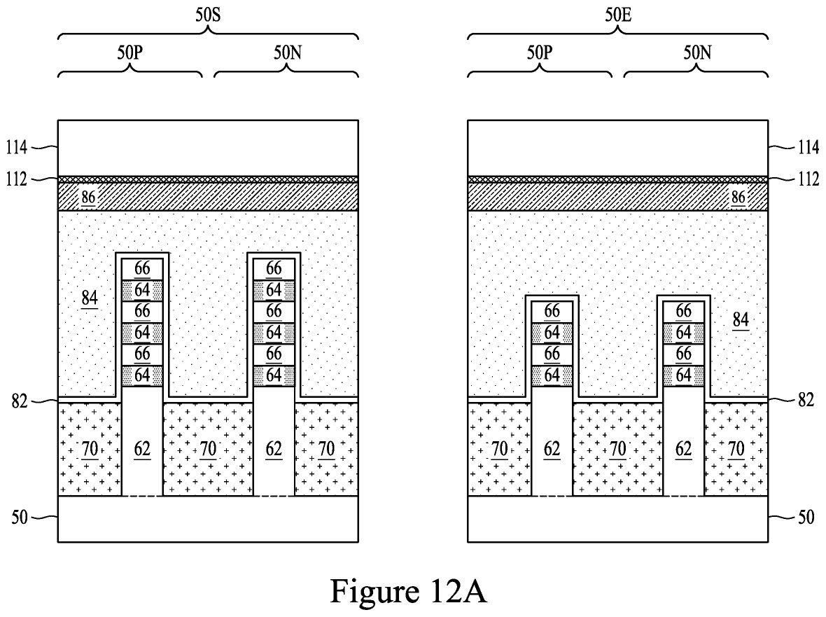

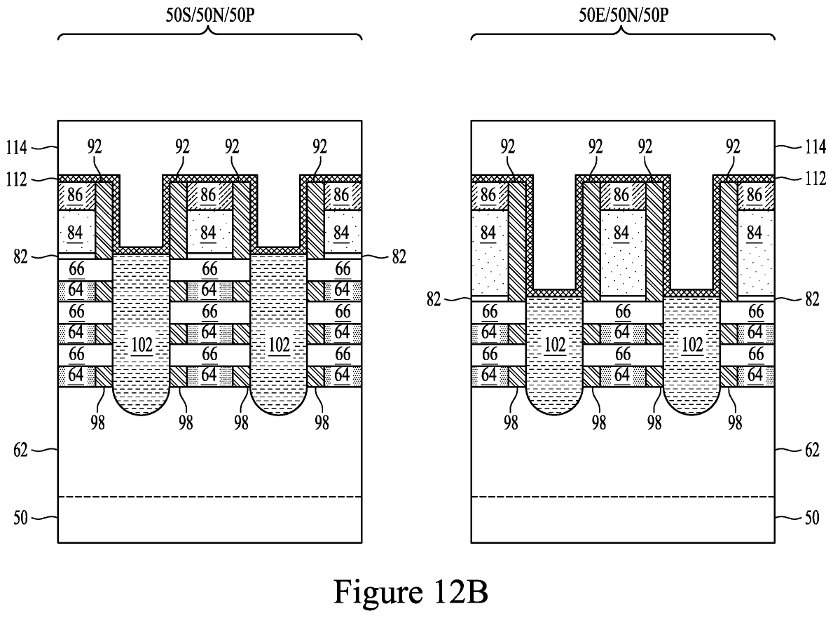

In FIGS. 12A-12B, a first ILD 114 is deposited over the epitaxial source/drain regions 102, the gate spacers 92, and the masks 86 (if present) or the dummy gates 84. The first ILD 114 may be formed of a dielectric material, which may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 112 is formed between the first ILD 114 and the epitaxial source/drain regions 102, the gate spacers 92, and the masks 86 (if present) or the dummy gates 84. The CESL 112 may be formed of a dielectric material having a high etching selectivity from the etching of the first ILD 114, such as, silicon nitride, silicon oxide, silicon oxynitride, or the like, which may be formed by any suitable deposition process, such as CVD, ALD, or the like.

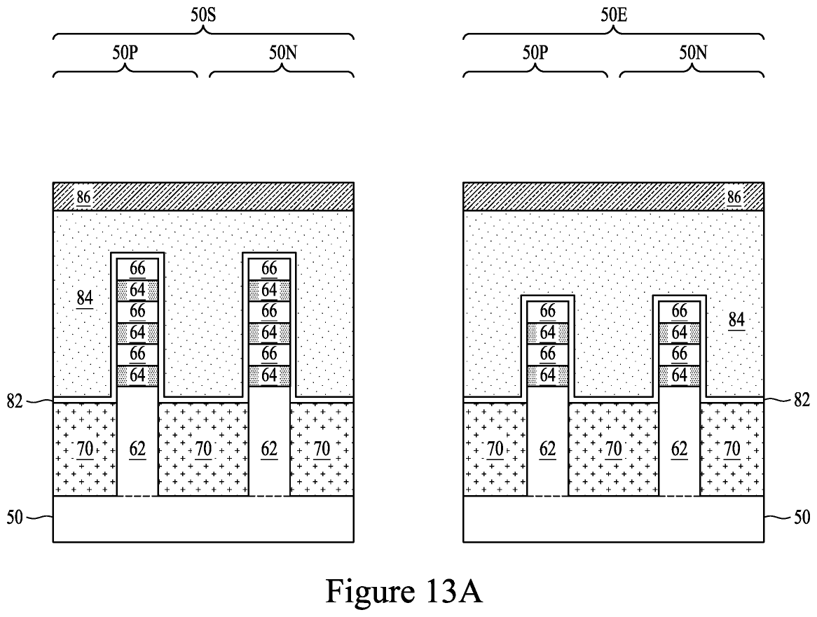

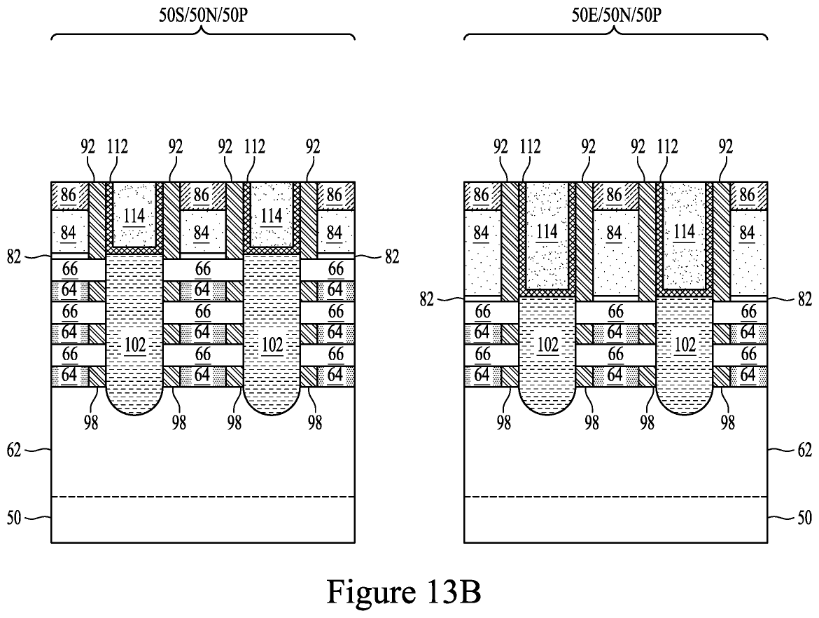

In FIGS. 13A-13B, a removal process is performed to level the top surfaces of the first ILD 114 with the top surfaces of the gate spacers 92 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 92 along sidewalls of the masks 86. After the planarization process, top surfaces of the first ILD 114, the gate spacers 92, and the masks 86 (if present) or the dummy gates 84 are substantially coplanar (within process variations). Accordingly, the top surfaces of the masks 86 (if present) or the dummy gates 84 are exposed through the first ILD 114.

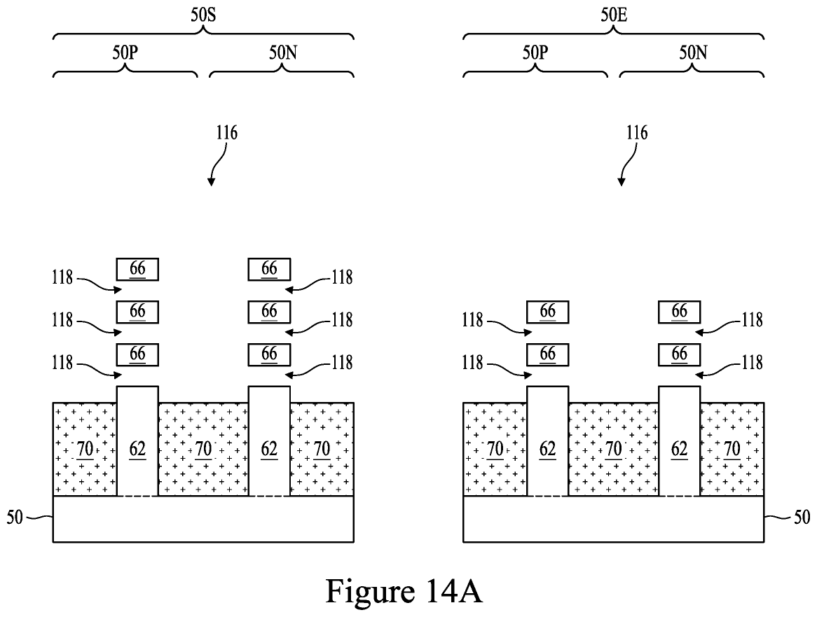

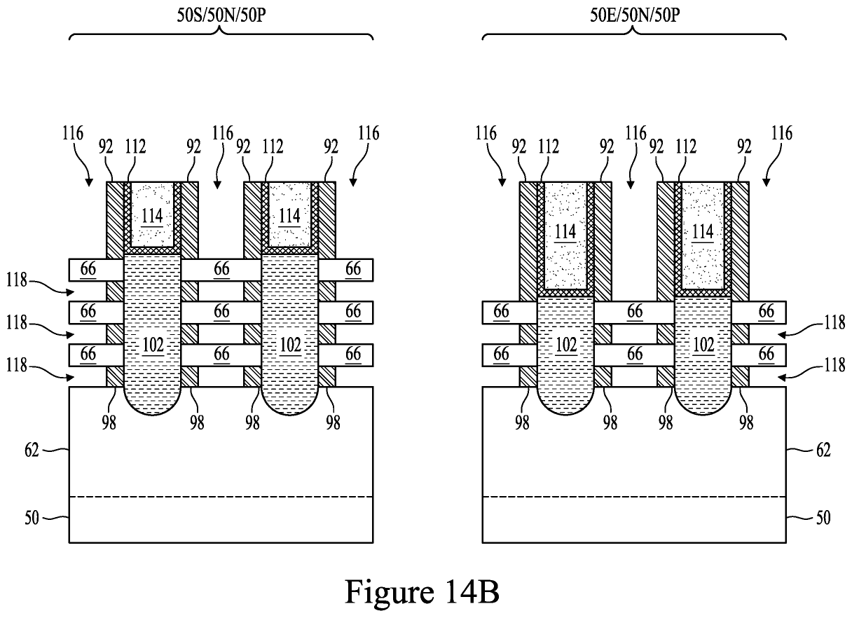

In FIGS. 14A-14B, the masks 86 (if present) and the dummy gates 84 are removed in one or more etching steps, so that recesses 116 are formed between the gate spacers 92. Portions of the dummy dielectrics 82 in the recesses 116 are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the first ILD 114 and the gate spacers 92. Each recesses 116 exposes and/or overlies portions of nanostructures 64, 66 which act as the channel regions in subsequently completed nanostructure-FETs. The nanostructures 64, 66 which act as the channel regions are disposed between neighboring pairs of the epitaxial source/drain regions 102. During the removal, the dummy dielectrics 82 may be used as etch stop layers when the dummy gates 84 are etched. The dummy dielectrics 82 may then be removed after the removal of the dummy gates 84.

The remaining portions of the first nanostructures 64 are then removed to form openings 118 in regions between the second nanostructures 66. The remaining portions of the first nanostructures 64 can be removed by any acceptable etch process that selectively etches the material of the first nanostructures 64 at a faster rate than the material of the second nanostructures 66. The etching may be isotropic. For example, when the first nanostructures 64 are formed of silicon germanium and the second nanostructures 66 are formed of silicon, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the second nanostructures 66 and expand the openings 118.

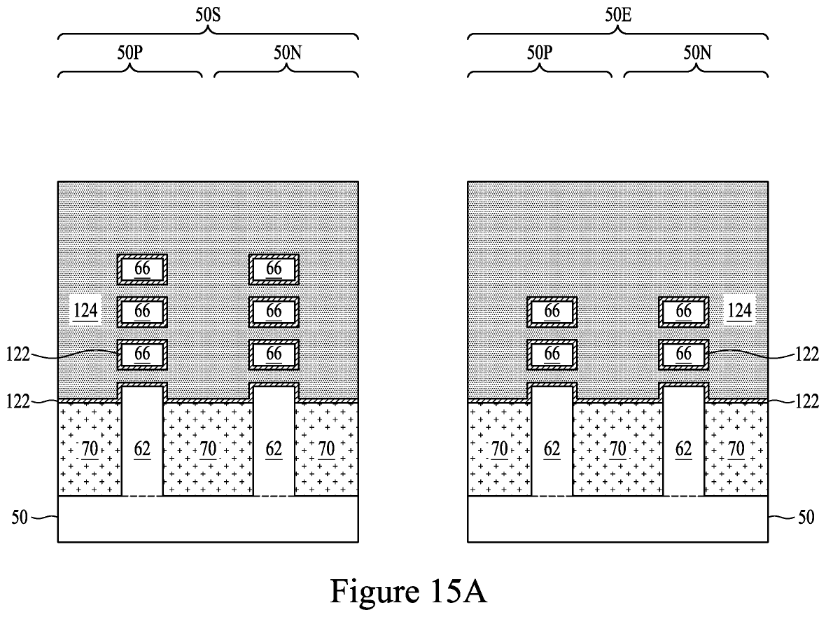

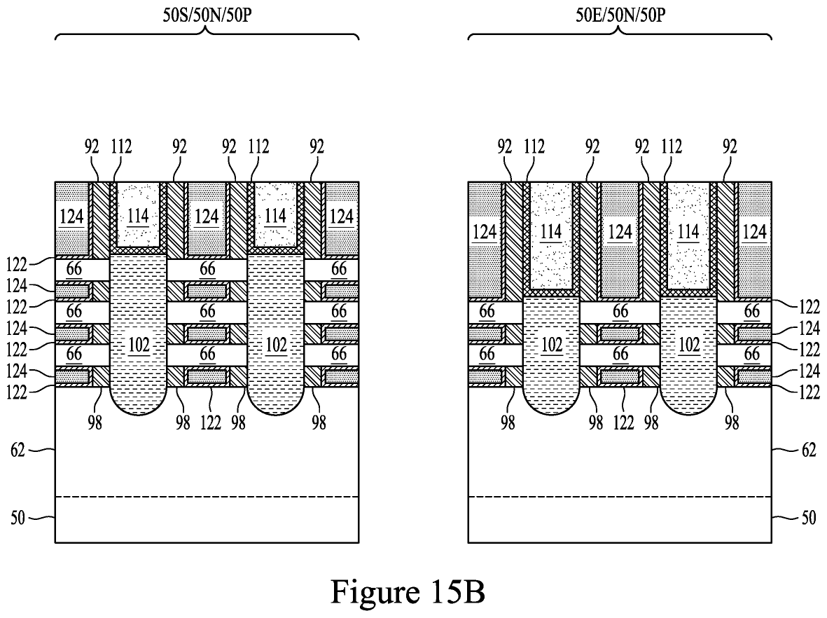

In FIGS. 15A-15B, gate dielectrics 122 and gate electrodes 124 are formed for replacement gates. Each respective pair of a gate dielectric 122 and a gate electrode 124 may be collectively referred to as a “gate structure.” Each gate structure is wrapped around a channel region of a nanostructure 66, such that the gate structure extends along sidewalls, a bottom surface, and a top surface of the nanostructure 66. Some of the gate structures also extend along sidewalls and/or a top surface of a fin 62.

The gate dielectrics 122 include one or more gate dielectric layer(s) disposed on the sidewalls and/or the top surfaces of the fins 62; on the top surfaces, the sidewalls, and the bottom surfaces of the channel regions of the nanostructures 66; on the sidewalls of the inner spacers 98 adjacent the epitaxial source/drain regions 102; and on the sidewalls of the gate spacers 92. The gate dielectrics 122 may be formed of an oxide such as silicon oxide or a metal oxide, a silicate such as a metal silicate, combinations thereof, multi-layers thereof, or the like. Additionally or alternatively, the gate dielectrics 122 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 122 may be formed by molecular-beam deposition (MBD), ALD, PECVD, or the like. Although single-layered gate dielectrics 122 are illustrated, the gate dielectrics 122 may include any number of interfacial layers and any number of main layers. For example, the gate dielectrics 122 may include an interfacial layer and an overlying high-k dielectric layer.

The gate electrodes 124 include one or more gate electrode layer(s) disposed over the gate dielectrics 122. The gate electrodes 124 may be formed of a metal-containing material such as titanium nitride, titanium oxide, tantalum nitride, tantalum carbide, tungsten, cobalt, ruthenium, aluminum, combinations thereof, multi-layers thereof, or the like. Although single-layered gate electrodes 124 are illustrated, the gate electrodes 124 may include any number of work function tuning layers, any number of barrier layers, any number of glue layers, and a fill material.

As an example to form the gate structures, one or more gate dielectric layer(s) may be deposited in the recesses 116 and the openings 118. The gate dielectric layer(s) may also be deposited on the top surfaces of the first ILD 114 and the gate spacers 92. Subsequently, one or more gate electrode layer(s) may be deposited on the gate dielectric layer(s), and in the remaining portions of the recesses 116 and the openings 118. A removal process may then be performed to remove the excess portions of the gate dielectric layer(s) and the gate electrode layer(s), which excess portions are over the top surfaces of the first ILD 114 and the gate spacers 92. In some embodiments, a planarization process such as a chemical mechanical polish (CMP), an etch-back process, combinations thereof, or the like may be utilized. The gate dielectric layer(s), after the removal process, have portions remaining in the recesses 116 and the openings 118 (thus forming the gate dielectrics 122). The gate electrode layer(s), after the removal process, have portions remaining in the recesses 116 and the openings 118 (thus forming the gate electrodes 124). When a planarization process it utilized, the top surfaces of the gate spacers 92, the first ILD 114, the gate dielectrics 122, and the gate electrodes 124 are coplanar (within process variations).

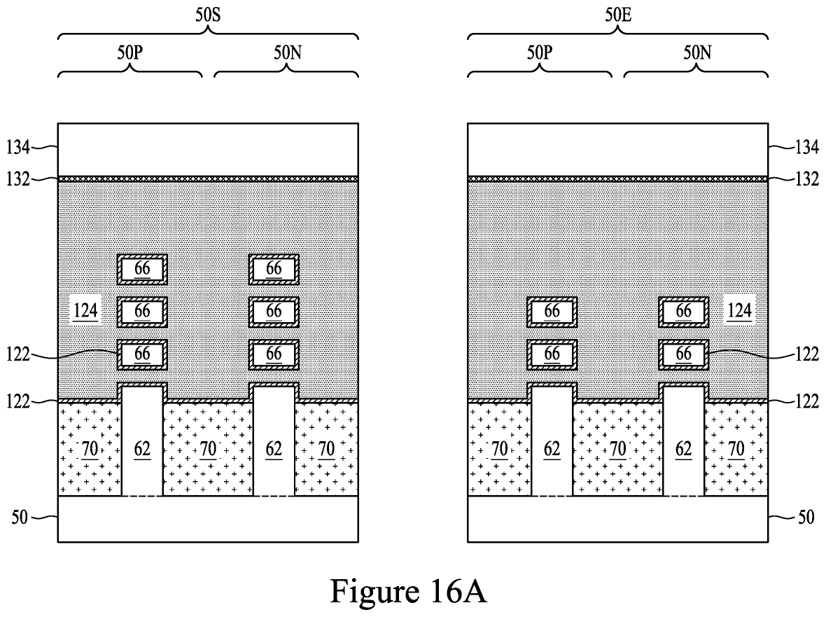

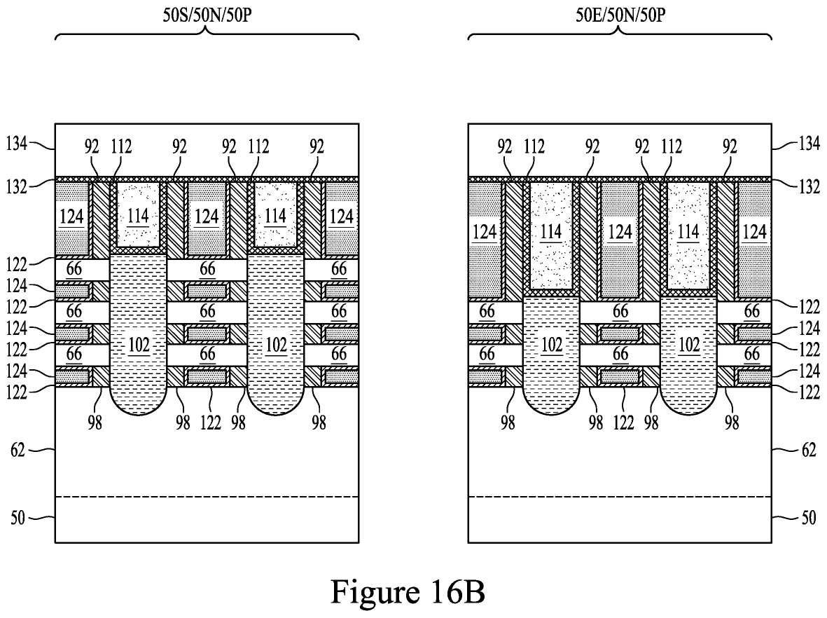

In FIGS. 16A-16B, a second ILD 134 is deposited over the gate spacers 92, the first ILD 114, the gate dielectrics 122, and the gate electrodes 124. In some embodiments, the second ILD 134 is a flowable film formed by a flowable CVD method. In some embodiments, the second ILD 134 is formed of a dielectric material such as PSG, BSG, BPSG, USG, or the like, which may be formed by any suitable deposition process, such as CVD, PECVD, or the like.

In some embodiments, an etch stop layer (ESL) 132 is formed between the second ILD 134 and the gate spacers 92, the first ILD 114, the gate dielectrics 122, and the gate electrodes 124. The ESL 132 may be formed of a dielectric material having a high etching selectivity from the etching of the second ILD 134, such as silicon nitride, silicon oxide, silicon oxynitride, or the like, which may be formed by any suitable deposition process, such as CVD, ALD, or the like.

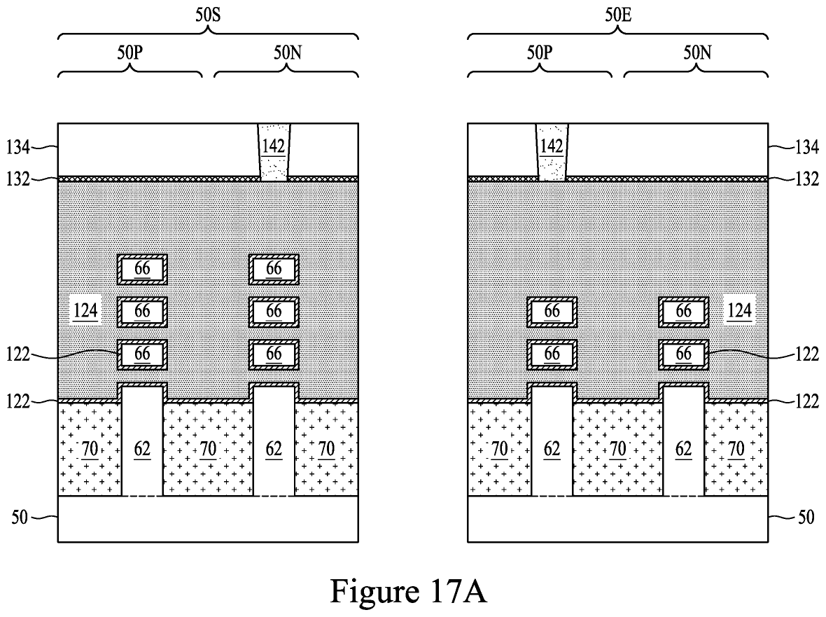

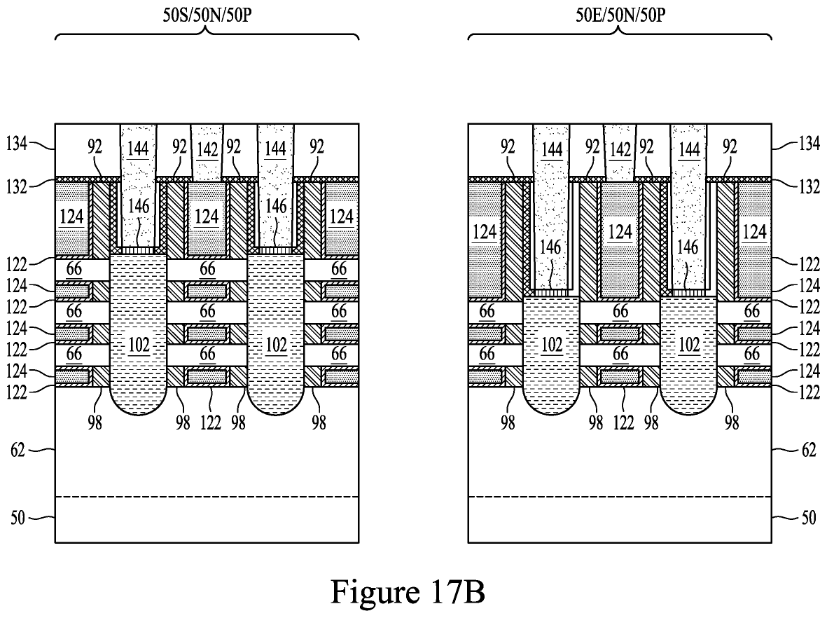

In FIGS. 17A-17B, gate contacts 142 and source/drain contacts 144 are formed to contact, respectively, the gate electrodes 124 and the epitaxial source/drain regions 102. The gate contacts 142 may be physically and electrically coupled to the gate electrodes 124. The source/drain contacts 144 may be physically and electrically coupled to the epitaxial source/drain regions 102.

As an example to form the gate contacts 142 and the source/drain contacts 144, openings for the gate contacts 142 are formed through the second ILD 134 and the ESL 132, and openings for the source/drain contacts 144 are formed through the second ILD 134, the ESL 132, the first ILD 114, and the CESL 112. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 134. The remaining liner and conductive material form the gate contacts 142 and the source/drain contacts 144 in the openings. The gate contacts 142 and the source/drain contacts 144 may be formed in distinct processes, or may be formed in the same process. Although shown as being formed in the same cross-sections, it should be appreciated that each of the gate contacts 142 and the source/drain contacts 144 may be formed in different cross-sections, which may avoid shorting of the contacts.

Optionally, metal-semiconductor alloy regions 146 are formed at the interfaces between the epitaxial source/drain regions 102 and the source/drain contacts 144. The metal-semiconductor alloy regions 146 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 146 can be formed before the material(s) of the source/drain contacts 144 by depositing a metal in the openings for the source/drain contacts 144 and then performing a thermal annealing process. The metal can be any metal capable of reacting with the semiconductor materials (e.g., silicon, silicon carbide, silicon germanium, germanium, etc.) of the epitaxial source/drain regions 102 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 144, such as from surfaces of the metal-semiconductor alloy regions 146. The material(s) of the source/drain contacts 144 can then be formed on the metal-semiconductor alloy regions 146.

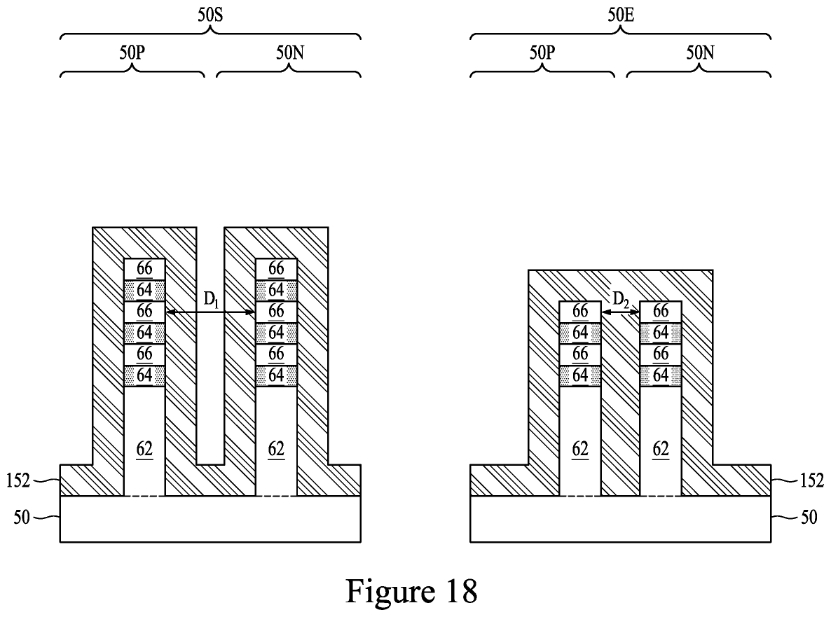

FIGS. 18-20 are views of intermediate stages in the manufacturing of nanostructure-FETs, in accordance with some embodiments. FIGS. 18, 19, and 20 illustrate cross-sectional views along a similar cross-section as reference cross-section A-A′ in FIG. 1. This embodiment is similar to the embodiment of FIGS. 2-17B, except in some regions (e.g., the high-efficiency region 50E), dielectric walls are formed between the second nanostructures 66 in an n-type region 50N and the second nanostructures 66 in an adjacent p-type region 50P. Each dielectric wall separates a channel region of an n-type device from a channel region of a p-type device to prevent shorting of the adjacent channel regions. The second nanostructures 66 in an n-type region 50N may thus be formed close to the second nanostructures 66 in an adjacent p-type region 50P.

In FIG. 18, a substrate is provided and multi-layer stack is formed over the substrate, in a similar manner as described for FIG. 2. Some layers of the multi-layer stack are removed from the high-efficiency region 50E, in a similar manner as described for FIG. 3. Next, fins 62 are formed in the substrate and nanostructures 64, 66 are formed in the multi-layer stack, in a similar manner as described for FIG. 4. In this embodiment, the trenches between the nanostructures 64, 66 have different widths. Specifically, the distance D₁ between adjacent nanostructures 64, 66 in the high-speed region 50S is greater than the distance D₂ between adjacent nanostructures 64, 66 in the high-efficiency region 50E. In some embodiments, the distance D₁ is in the range of 10 nm to 100 nm, and the distance D₂ is less than or equal to 50 nm.

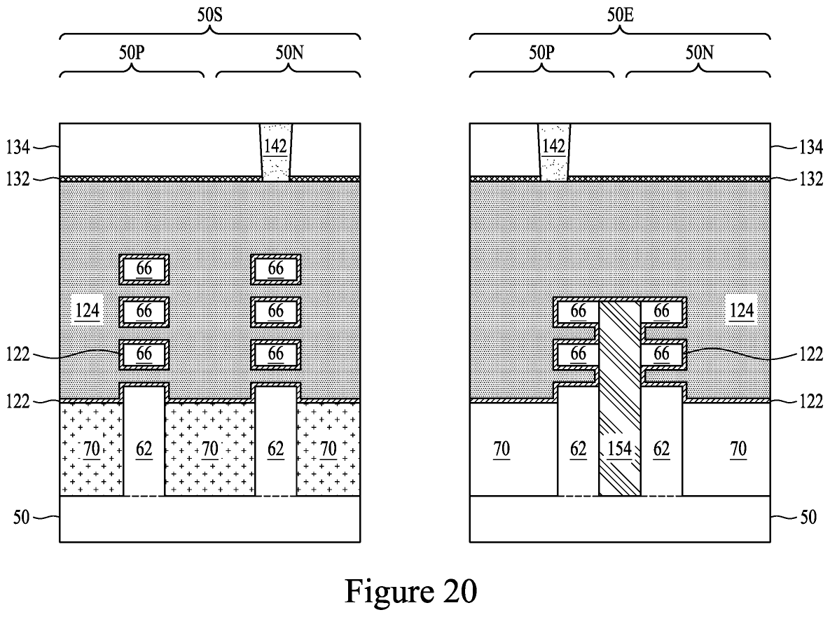

A dielectric layer 152 for dielectric walls is then conformally formed in the trenches between the fins 62 and the nanostructures 64, 66, such that it conformally lines the trenches. The dielectric layer 152 is formed of a dielectric material having a high etching selectivity from the etching of the isolation regions 70 (see FIG. 20). Acceptable dielectric materials may include oxides such as silicon oxide or aluminum oxide, nitrides such as silicon nitride or aluminum nitride, or the like, which may be formed by a deposition process such as chemical vapor deposition (CVD), atomic layer deposition (ALD), or the like. Because the trenches between and the nanostructures 64, 66 have different widths, they are filled with different amount of dielectric material. Specifically, the trenches between the nanostructures 64, 66 in the high-speed region 50S are not completely filled by the dielectric layer 152, while the trenches between the nanostructures 64, 66 in the high-efficiency region 50E are completely filled (or overfilled) by the dielectric layer 152.

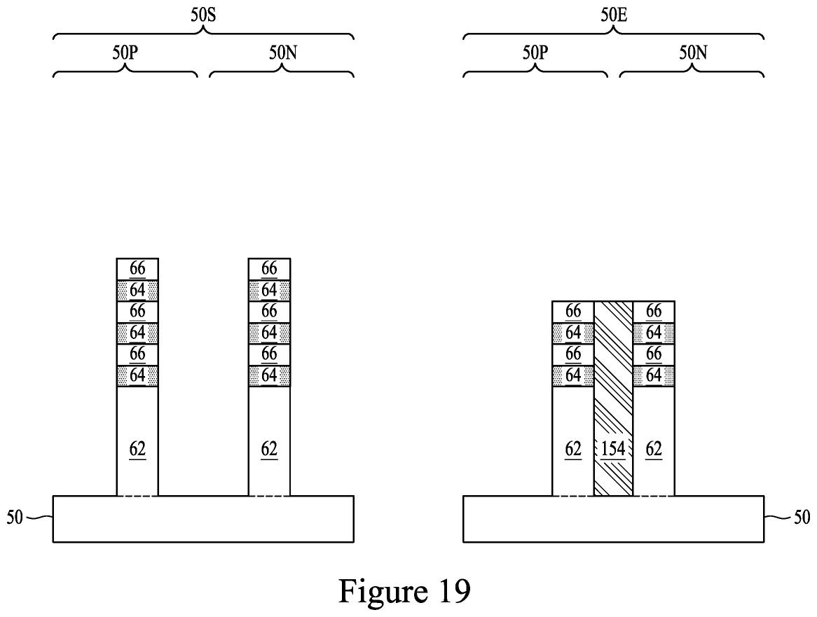

In FIG. 19, the dielectric layer 152 is etched back to remove some portions of the dielectric layer 152. Specifically, the portions of the dielectric layer 152 between the nanostructures 64, 66 in the high-speed region 50S are removed by the etch-back process, thus reforming the trenches between the nanostructures 64, 66 in the high-speed region 50S. The dielectric layer 152 is etched back using any acceptable etching technique. After the etch-back process is complete, the remaining portions of the dielectric layer 152 are in the trenches between the nanostructures 64, 66 in the high-efficiency region 50E. The remaining portions of the dielectric layer 152 form dielectric walls 154 separating the nanostructures 64, 66 in the high-efficiency region 50E. Forming the dielectric walls 154 between the nanostructures 64, 66 in the high-efficiency region 50E allows the nanostructures 64, 66 in the high-efficiency region 50E to be formed closer together than the nanostructures 64, 66 in the high-speed region 50S. Device density may thus be improved.

In FIG. 20, appropriate processing steps as previously described are performed to complete the manufacturing of the nanostructure-FETs. In this embodiment, the dielectric walls 154 are formed in the high-efficiency region 50E but not the high-speed region 505. In another embodiment, the dielectric walls 154 may be formed in both the high-efficiency region 50E and the high-speed region 50S.

As previously noted, the manufacturing of the nanostructure-FETs may be performed using lithography mask(s) that are generated based on a device layout. The device layout may be designed in a design process before the manufacturing of the nanostructure-FETs. The design process may include laying out cells corresponding to desired regions, including the high-efficiency region 50E and the high-speed region 50S. For example, a device layout for a semiconductor device may be designed by placing high-efficiency cells in the device layout where high-efficiency regions 50E are desired and by placing high-speed cells in the device layout where high-speed regions 50S are desired.

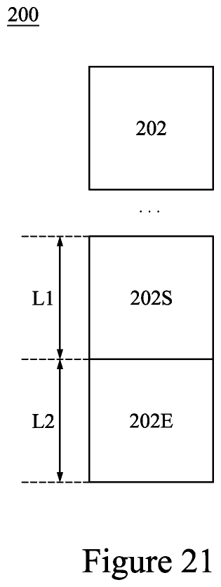

FIG. 21 illustrates a device layout 200 for a semiconductor device, in accordance with some embodiments. The device layout 200 is shown in a top-down view of the semiconductor device. The device layout 200 includes multiple cells 202. Each cell 202 includes a definition of functional features for a device (e.g., semiconductor fins, nanowires, etc.), isolation features for the devices (e.g., STI regions), etc. In some embodiments, each cell 202 corresponds to a region (e.g., the high-efficiency region 50E or the high-speed region 505, previously described) of the semiconductor device. Accordingly, during the design process, high-efficiency devices (e.g., transistors) may be placed by placing high-efficiency cells 202E in desired locations of the device layout 200, and high-speed devices (e.g., transistors) may be placed by placing high-speed cells 202S in desired locations of the device layout 200. In some embodiments, each of the cells 202 defines devices for a CMOS circuit. For example, a cell 202 may define a p-type transistor and an n-type transistor for a CMOS inverter.

In the device layout 200, a high-speed cell 202S is placed directly adjacent to a high-efficiency cell 202E. Accordingly, no other cells are disposed between a high-speed cell 202S and a high-efficiency cell 202E. In this embodiment, each cell 202 has a same size. According, a size of a high-speed cell 202S is the same as a size of a high-efficiency cell 202E. In this context, the size of a cell 202 refers to the dimensions of a cell 202 in at least one direction, such as in two directions, of the top-down view. Therefore, a length L1 of a high-speed cell 202S is the same as a length L2 of a high-efficiency cell 202E, where the length L1 and the length L2 are measured in the same direction of the device layout 200 (e.g., the vertical direction in the top-down view). For example, the high-efficiency cell 202E and the high-speed cell 202S may have the same length along rows and/or columns of the device layout 200. In some embodiments where the length L1 is the same as the length L2, the lengths L1 and L2 are each in the range of 50 nm to 300 nm. The size of a cell 202 is determined by the dimensions of the functional and isolation features defined by that cell. In this embodiment where the length L1 and the length L2 are equal to one another, the functional and isolation features defined by the high-speed cell 202S have the same dimensions as the functional and isolation features defined by the high-efficiency cell 202E.

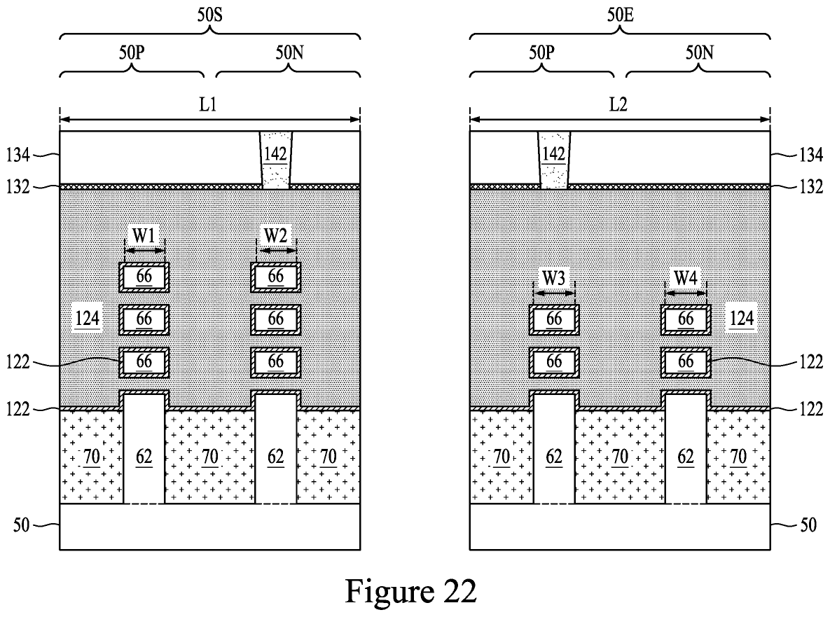

FIG. 22 is a view a high-speed cell 202S and a high-efficiency cell 202E of the device layout 200 of FIG. 21, in accordance with some embodiments. FIG. 22 illustrates cross-sectional views along a similar cross-section as reference cross-section A-A′ in FIG. 1. The devices defined by the high-speed cell 202S have more channel regions than the devices defined by the high-efficiency cell 202E. Specifically, the devices (e.g., transistors) of the high-speed cell 202S include more nanostructures 66 than the devices (e.g., transistors) of the high-efficiency cell 202E. In some embodiments, the devices (e.g., transistors) of the high-speed cell 202S include five nanostructures 66 and the devices (e.g., transistors) of the high-efficiency cell 202E include four nanostructures 66. In this embodiment the high-efficiency cell 202E does not include a dielectric wall, and as a result, the gate structures in the high-efficiency cell 202E extend around the same quantity of sides (e.g., four sides) of the nanostructures 66 as the gate structures in the high-speed cell 202S.

In this embodiment, the width of the nanostructures 66 in the high-speed cell 202S is the same as the width of the nanostructures 66 in the high-efficiency cell 202E. Further, the width of the nanostructures 66 in the p-type regions 50P is the same as the width of the nanostructures 66 in the n-type regions 50N. Accordingly, a width W1 of the nanostructures 66 in the p-type region 50P of the high-speed cell 202S, a width W2 of the nanostructures 66 in the n-type region 50N of the high-speed cell 202S, a width W3 of the nanostructures 66 in the p-type region 50P of the high-efficiency cell 202E, and a width W4 of the nanostructures 66 in the n-type region 50N of the high-efficiency cell 202E are equal to one another. In some embodiments where the widths W1, W2, W3, and W4 are equal to one another, the widths W1, W2, W3, and W4 are each in the range of 5 nm to 100 nm.

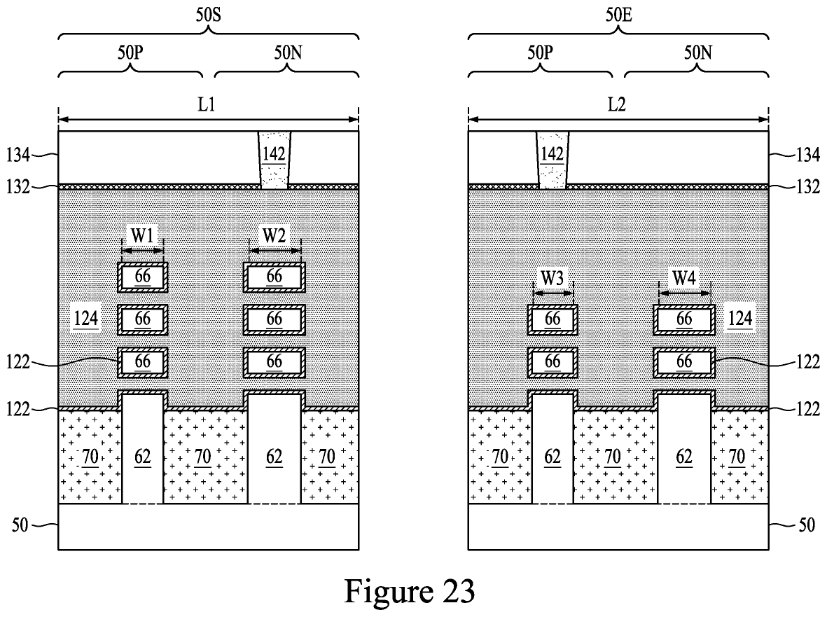

FIG. 23 is a view a high-speed cell 202S and a high-efficiency cell 202E of the device layout 200 of FIG. 21, in accordance with some embodiments. This embodiment is similar to the embodiment of FIG. 22, except the width of the nanostructures 66 in the p-type regions 50P is different than the width of the nanostructures 66 in the n-type regions 50N. In this example, the width of the nanostructures 66 in the p-type regions 50P is less than the width of the nanostructures 66 in the n-type regions 50N, but the width of the nanostructures 66 in the p-type regions 50P may be greater than the width of the nanostructures 66 in the n-type regions 50N. Accordingly, a width W1 of the nanostructures 66 in the p-type region 50P of the high-speed cell 202S is different (e.g., less) than a width W2 of the nanostructures 66 in the n-type region 50N of the high-speed cell 202S, and a width W3 of the nanostructures 66 in the p-type region 50P of the high-efficiency cell 202E is different (e.g., less) than a width W4 of the nanostructures 66 in the n-type region 50N of the high-efficiency cell 202E. In this embodiment where the length L1 of the high-speed cell 202S is the same as the length L2 of the high-efficiency cell 202E, the widths W1 and W3 are equal to one another and the widths W2 and W4 are equal to one another. In some embodiments where the widths W1 and W3 are equal to one another and the widths W2 and W4 are equal to one another, the widths W1 and W3 are each in the range of 5 nm to 99 nm and the widths W2 and W4 are each in the range of 6 nm to 100 nm.

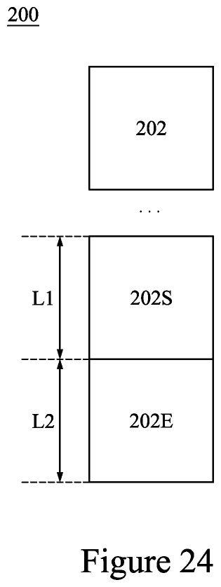

FIG. 24 illustrates a device layout 200 for a semiconductor device, in accordance with some embodiments. This embodiment is similar to the embodiment of FIG. 21, except the length L1 of the high-speed cell 202S is different (e.g., greater) than the length L2 of the high-efficiency cell 202E. In some embodiments where the length L1 is different than the length L2, the length L1 is in the range of 51 nm to 300 nm and the length L2 is in the range of 50 nm to 299 nm. In this embodiment where the length L1 is different than the length L2, the functional and isolation features defined by the high-speed cell 202S have different dimensions than the functional and isolation features defined by the high-efficiency cell 202E.

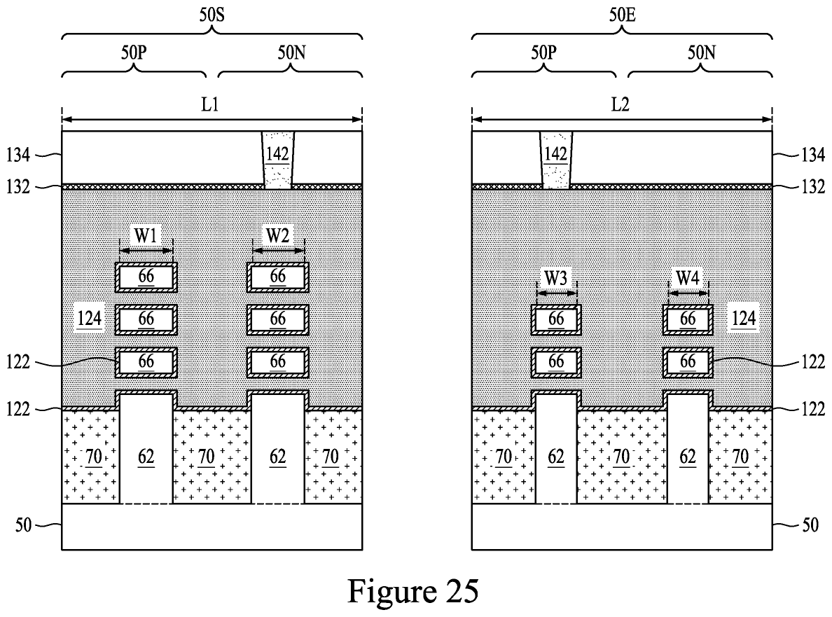

FIG. 25 is a view a high-speed cell 202S and a high-efficiency cell 202E of the device layout 200 of FIG. 24, in accordance with some embodiments. FIG. 25 illustrates cross-sectional views along a similar cross-section as reference cross-section A-A′ in FIG. 1. Similar to the embodiments described for FIGS. 22-23, the devices defined by the high-speed cell 202S have more channel regions than the devices defined by the high-efficiency cell 202E.

In this embodiment, the width of the nanostructures 66 in the high-speed cell 202S is different than the width of the nanostructures 66 in the high-efficiency cell 202E. In this example, the width of the nanostructures 66 in the high-speed cell 202S is greater than the nanostructures 66 in the high-efficiency cell 202E, but the width of the nanostructures 66 in the high-speed cell 202S may be less than the width of the nanostructures 66 in the high-efficiency cell 202E. Further, the width of the nanostructures 66 in the p-type regions 50P is the same as the width of the nanostructures 66 in the n-type regions 50N. Accordingly, a width W1 of the nanostructures 66 in the p-type region 50P of the high-speed cell 202S is the same as than a width W2 of the nanostructures 66 in the n-type region 50N of the high-speed cell 202S, and a width W3 of the nanostructures 66 in the p-type region 50P of the high-efficiency cell 202E is the same as a width W4 of the nanostructures 66 in the n-type region 50N of the high-efficiency cell 202E. In this embodiment where the length L1 of the high-speed cell 202S is different (e.g., greater) than the length L2 of the high-efficiency cell 202E, the widths W1 and W2 are different (e.g., greater) than the widths W3 and W4. In some embodiments where the widths W1 and W2 are different (e.g., greater) than the widths W3 and W4, the widths W1 and W2 are each in the range of 6 nm to 100 nm and the widths W3 and W4 are each in the range of 5 nm to 99 nm.

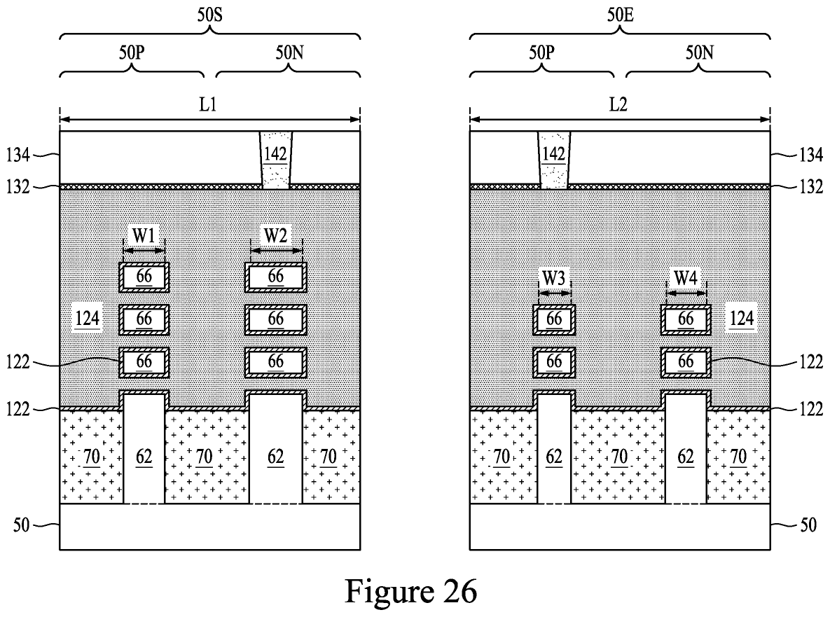

FIG. 26 is a view a high-speed cell 202S and a high-efficiency cell 202E of the device layout 200 of FIG. 24, in accordance with some embodiments. This embodiment is similar to the embodiment of FIG. 25, except the width of the nanostructures 66 in the p-type regions 50P is different than the width of the nanostructures 66 in the n-type regions 50N. In this example, the width of the nanostructures 66 in the p-type regions 50P is less than the width of the nanostructures 66 in the n-type regions 50N, but the width of the nanostructures 66 in the p-type regions 50P may be greater than the width of the nanostructures 66 in the n-type regions 50N. Accordingly, a width W1 of the nanostructures 66 in the p-type region 50P of the high-speed cell 202S is different (e.g., less) than a width W2 of the nanostructures 66 in the n-type region 50N of the high-speed cell 202S, and a width W3 of the nanostructures 66 in the p-type region 50P of the high-efficiency cell 202E is different (e.g., less) than a width W4 of the nanostructures 66 in the n-type region 50N of the high-efficiency cell 202E. In this embodiment where the length L1 of the high-speed cell 202S is different (e.g., greater) than the length L2 of the high-efficiency cell 202E, the width W1 is different (e.g., greater) than the width W3 and the width W2 is different (e.g., greater) than the width W4. In some embodiments where the width W1 is different (e.g., greater) than the width W3 and the width W2 is different (e.g., greater) than the width W4, the width W1 is in the range of 6 nm to 99 nm, the width W2 is in the range of 7 nm to 100 nm, the width W3 is in the range of 5 nm to 98 nm, and the width W4 is in the range of 6 nm to 99 nm.

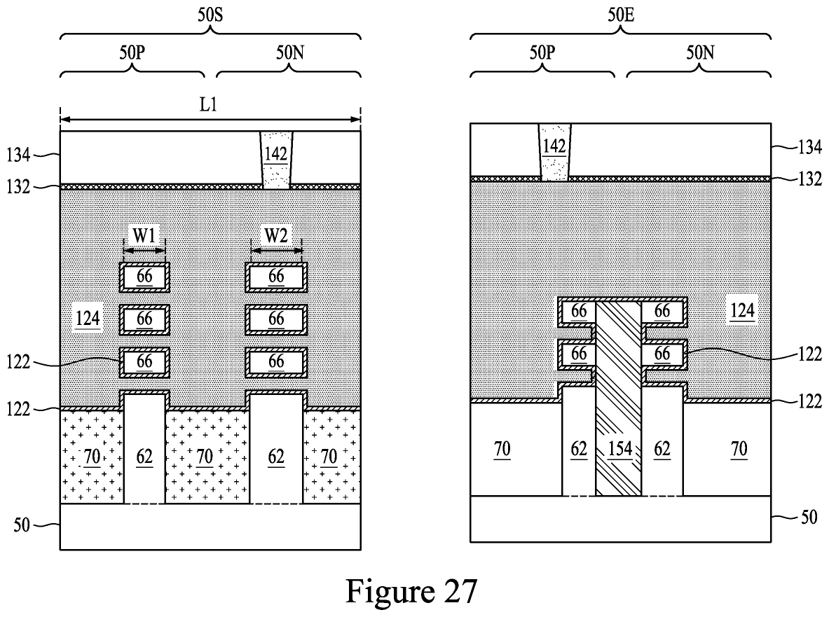

FIG. 27 is a view a high-speed cell 202S and a high-efficiency cell 202E of the device layout 200 of FIG. 24, in accordance with some embodiments. This embodiment is similar to the embodiment of FIG. 26, except the high-efficiency cell 202E includes a dielectric wall 154 between the second nanostructures 66 in the n-type region 50N and the second nanostructures 66 in the p-type region 50P. In this embodiment, the gate structures in the high-efficiency cell 202E extend around a different quantity of sides of the nanostructures 66 than the gate structures in the high-speed cell 202S. Specifically, the gate structures in the high-efficiency cell 202E extend around three sides of the nanostructures 66 while the gate structures in the high-speed cell 202S extend around four sides of the nanostructures 66

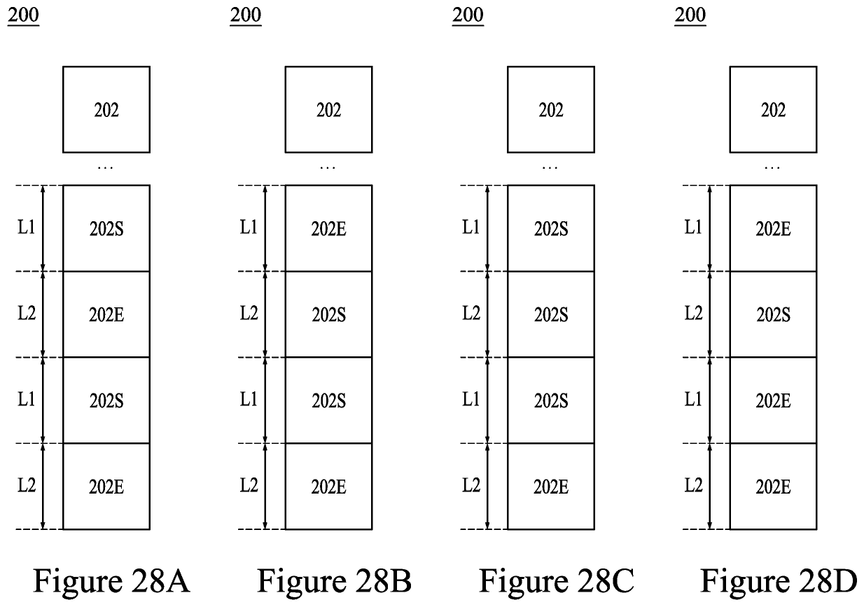

FIGS. 28A-28D illustrates device layouts 200 for a semiconductor device, in accordance with some embodiments. These embodiments are similar to the embodiment of FIG. 21, except a plurality of cells 202 (including high-efficiency cells 202E and high-speed cells 202S) are placed such that they are interleaved in a repeating sequence along the same direction of a device layout 200 (e.g., the vertical direction in the top-down view). For example, the high-efficiency cells 202E and the high-speed cells 202S may be interleaved in a repeating sequence along rows and/or columns of a device layout 200. The repeating sequence has an interleaving ratio of the high-efficiency cells 202E to the high-speed cells 202S. The interleaving ratio may be in the range of 2:1 to 1:3, such as in the range of 1:1 to 1:3. In some embodiments, the interleaving ratio is 1:1, such that the repeating sequence alternates between a high-efficiency cell 202E and a high-speed cell 202S along the same direction, as illustrated by FIG. 28A. In some embodiments, the interleaving ratio is 1:2, such that the repeating sequence alternates between a high-efficiency cell 202E and two high-speed cells 202S along the same direction, as illustrated by FIG. 28B. In some embodiments, the interleaving ratio is 1:3, such that the repeating sequence alternates between a high-efficiency cell 202E and three high-speed cells 202S along the same direction, as illustrated by FIG. 28C. In some embodiments, the interleaving ratio is 2:1, such that the repeating sequence alternates between two high-efficiency cells 202E and a high-speed cell 202S along the same direction, as illustrated by FIG. 28D.

The cells 202 of these device layouts 200 may have any desired size. In the illustrated embodiments, the size of the high-speed cells 202S is the same as the size of the high-efficiency cells 202E. In other embodiments, the size of the high-speed cells 202S is different (e.g., greater) than the size of the high-efficiency cells 202E.

In the previously described embodiments, two types of cells 202 (high-efficiency cells 202E and high-speed cells 202S) are utilized. However, it should be appreciated that embodiment layouts may include more than two types of cells 202, such as three types of cells 202. More generally, any desirable types of cells 202 may be utilized, where each type of cell 202 defines devices (e.g., transistors) with a different quantity of nanostructures 66.

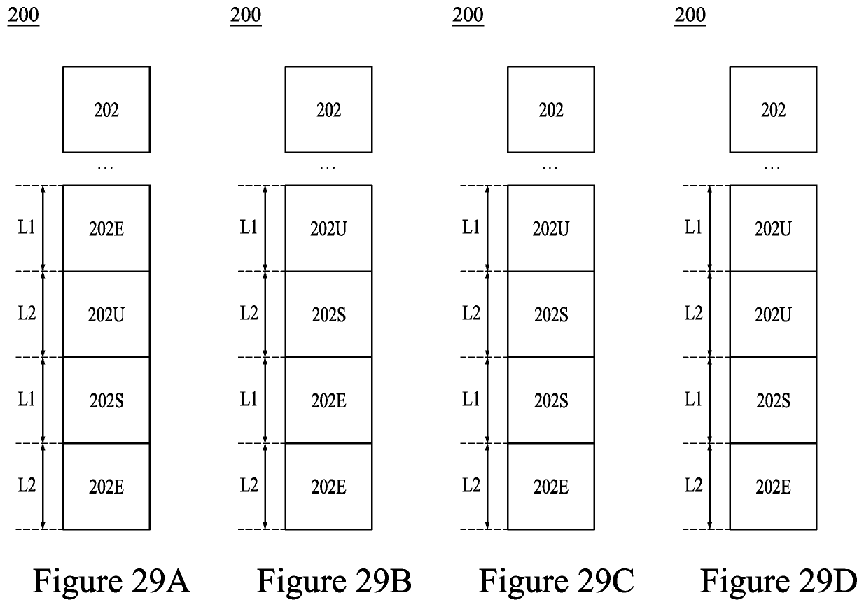

FIGS. 29A-29D illustrates device layouts 200 for a semiconductor device, in accordance with some embodiments. These embodiments are similar to the embodiment of FIG. 21, except the plurality of cells 202 includes high-efficiency cells 202E, high-speed cells 202S, and ultra-high-efficiency cells 202U. The ultra-high-efficiency cells 202U define devices with fewer nanostructures 66 than those defined by the high-efficiency cells 202E. In some embodiments, the high-speed cells 202S define devices with five nanostructures 66, the high-efficiency cells 202E define devices with four nanostructures 66, and the ultra-high-efficiency cells 202U define devices with three nanostructures 66.

The cells 202 are placed such that they are interleaved in a repeating sequence along the same direction of a device layout 200 (e.g., the vertical direction in the top-down view), similar to the embodiments of FIGS. 28A-28D. The repeating sequence has an interleaving ratio of the high-efficiency cells 202E to the high-speed cells 202S and to the ultra-high-efficiency cells 202U. In some embodiments, the interleaving ratio is 1:1:1, such that the repeating sequence alternates between a high-efficiency cell 202E, a high-speed cell 202S, and an ultra-high-efficiency cell 202U along the same direction, as illustrated by FIG. 29A. In some embodiments, the interleaving ratio is 2:1:1, such that the repeating sequence alternates between two high-efficiency cells 202E, a high-speed cell 202S, and an ultra-high-efficiency cell 202U along the same direction, as illustrated by FIG. 29B. In some embodiments, the interleaving ratio is 1:2:1, such that the repeating sequence alternates between a high-efficiency cell 202E, two high-speed cells 202S, and an ultra-high-efficiency cell 202U along the same direction, as illustrated by FIG. 29C. In some embodiments, the interleaving ratio is 1:1:2, such that the repeating sequence alternates between a high-efficiency cell 202E, a high-speed cell 202S, and two ultra-high-efficiency cells 202U along the same direction, as illustrated by FIG. 29D.

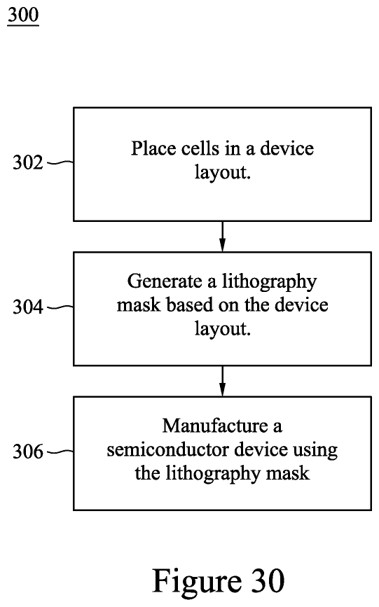

FIG. 30 is a flow diagram of a method 300 of forming a semiconductor device. The method 300 may be utilized to form any of the previously described semiconductor devices. In step 302, cells are placed in a device layout. The device layout may be any of the previously described device layouts, and the cells may be any of the previously described cells. In step 304, a lithography mask is generated based on the device layout. The lithography mask may be any of the previously described lithography masks. In step 306, a semiconductor device is manufactured using the lithography mask. The semiconductor device may be manufactured using any of the previously described manufacturing steps.

Embodiments may achieve advantages. The high-efficiency cells 202E and the high-speed cells 202S defining transistors with different quantities of nanostructures 66 allows the high-efficiency cells 202E and the high-speed cells 202S to have different work functions. When the cells 202 have the same size (in the top-down view), they may still include devices with different work functions. Device performance may thus be modulated without scaling up device sizes.

In an embodiment, a method includes: placing a first cell in a device layout, the first cell defining a first transistor, the first transistor including a first quantity of first nanostructures; placing a second cell in the device layout directly adjacent to the first cell, the second cell defining a second transistor, the second transistor including a second quantity of second nanostructures, the second quantity being different than the first quantity; generating a lithography mask based on the device layout; and manufacturing a semiconductor device using the lithography mask. In some embodiments of the method, a first size of the first cell is the same as a second size of the second cell. In some embodiments of the method, a first size of the first cell is different than a second size of the second cell. In some embodiments of the method, the first transistor further includes a first gate structure extending around a third quantity of sides of each of the first nanostructures, and the second transistor further includes a second gate structure extending around the third quantity of sides of each of the second nanostructures. In some embodiments of the method, the first transistor further includes a first gate structure extending around a third quantity of sides of each of the first nanostructures, and the second transistor further includes a second gate structure extending around a fourth quantity of sides of each of the second nanostructures, the fourth quantity being different than the third quantity. In some embodiments, the method further includes: placing a third cell in the device layout directly adjacent to the second cell, the third cell defining a third transistor, the third transistor including a third quantity of third nanostructures, the third quantity being different than the second quantity and the first quantity. In some embodiments of the method: the first transistor is a first p-type transistor, the first cell further includes a first n-type transistor, the first n-type transistor includes the first quantity of third nanostructures, a first width of the first nanostructures is different than a third width of the third nanostructures; and the second transistor is a second p-type transistor, the second cell further includes a second n-type transistor, the second n-type transistor includes the second quantity of fourth nanostructures, a second width of the second nanostructures is different than a fourth width of the fourth nanostructures. In some embodiments of the method, the first width of the first nanostructures is different than the second width of the second nanostructures, and the third width of the third nanostructures is different than the fourth width of the fourth nanostructures. In some embodiments of the method, the first width of the first nanostructures is the same as the second width of the second nanostructures, and the third width of the third nanostructures is the same as the fourth width of the fourth nanostructures.

In an embodiment, a method includes: placing first cells in a device layout, the first cells each defining a first transistor, the first transistor including a first quantity of first nanostructures; placing second cells in the device layout, the second cells each defining a second transistor, the second transistor including a second quantity of second nanostructures, the second quantity being different than the first quantity, the first cells and the second cells being interleaved in a repeating sequence along a direction of the device layout; generating a lithography mask based on the device layout; and manufacturing a semiconductor device using the lithography mask. In some embodiments of the method, the repeating sequence has an interleaving ratio of a third quantity of the first cells to a fourth quantity of the second cells, interleaving ratio being in a range of 1:1 to 1:3. In some embodiments of the method, the third quantity is the same as the fourth quantity. In some embodiments of the method, the third quantity is different than the fourth quantity. In some embodiments, the method further includes: placing third cells in the device layout, the third cells each defining a third transistor, the third transistor including a third quantity of third nanostructures, the third quantity being different than the first quantity and the second quantity, the first cells, the second cells, and the third cells being interleaved in the repeating sequence along the direction of the device layout. In some embodiments of the method, a first length of the first cells is the same as a second length of the second cells. In some embodiments of the method, a first length of the first cells is different than a second length of the second cells.

In an embodiment, a device includes: a first inverter including: a first p-type transistor including first nanostructures, the first nanostructures having a first width; and a first n-type transistor including second nanostructures, the second nanostructures having a second width, the second width different than the first width; and a second inverter including: a second p-type transistor including third nanostructures, the third nanostructures having a third width, the third width different than the first width; and a second n-type transistor including fourth nanostructures, the fourth nanostructures having a fourth width, the fourth width different than the third width and the second width. In some embodiments of the device, the second width is greater than the first width. In some embodiments of the device, the fourth width is greater than the third width. In some embodiments of the device, the fourth width is less than the first width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
placing a first cell in a device layout, the first cell defining a first transistor, the first transistor comprising a first quantity of first nanostructures;
placing a second cell in the device layout directly adjacent to the first cell, the second cell defining a second transistor, the second transistor comprising a second quantity of second nanostructures, the second quantity being different than the first quantity;
generating a lithography mask based on the device layout; and
manufacturing a semiconductor device using the lithography mask.

2. The method of claim 1, wherein a first size of the first cell is the same as a second size of the second cell.

3. The method of claim 1, wherein a first size of the first cell is different than a second size of the second cell.

4. The method of claim 1, wherein the first transistor further comprises a first gate structure extending around a third quantity of sides of each of the first nanostructures, and the second transistor further comprises a second gate structure extending around the third quantity of sides of each of the second nanostructures.

5. The method of claim 1, wherein the first transistor further comprises a first gate structure extending around a third quantity of sides of each of the first nanostructures, and the second transistor further comprises a second gate structure extending around a fourth quantity of sides of each of the second nanostructures, the fourth quantity being different than the third quantity.

6. The method of claim 1 further comprising:
placing a third cell in the device layout directly adjacent to the second cell, the third cell defining a third transistor, the third transistor comprising a third quantity of third nanostructures, the third quantity being different than the second quantity and the first quantity.

7. The method of claim 1, wherein:
the first transistor is a first p-type transistor, the first cell further comprises a first n-type transistor, the first n-type transistor comprises the first quantity of third nanostructures, a first width of the first nanostructures is different than a third width of the third nanostructures; and
the second transistor is a second p-type transistor, the second cell further comprises a second n-type transistor, the second n-type transistor comprises the second quantity of fourth nanostructures, a second width of the second nanostructures is different than a fourth width of the fourth nanostructures.

8. The method of claim 7, wherein the first width of the first nanostructures is different than the second width of the second nanostructures, and the third width of the third nanostructures is different than the fourth width of the fourth nanostructures.

9. The method of claim 8, wherein the first width of the first nanostructures is the same as the second width of the second nanostructures, and the third width of the third nanostructures is the same as the fourth width of the fourth nanostructures.

10. A method comprising:
placing first cells in a device layout, the first cells each defining a first transistor, the first transistor comprising a first quantity of first nanostructures;
placing second cells in the device layout, the second cells each defining a second transistor, the second transistor comprising a second quantity of second nanostructures, the second quantity being different than the first quantity, the first cells and the second cells being interleaved in a repeating sequence along a direction of the device layout;
generating a lithography mask based on the device layout; and
manufacturing a semiconductor device using the lithography mask.

11. The method of claim 10, wherein the repeating sequence has an interleaving ratio of a third quantity of the first cells to a fourth quantity of the second cells, interleaving ratio being in a range of 1:1 to 1:3.

12. The method of claim 11, wherein the third quantity is the same as the fourth quantity.

13. The method of claim 11, wherein the third quantity is different than the fourth quantity.

14. The method of claim 10 further comprising:
placing third cells in the device layout, the third cells each defining a third transistor, the third transistor comprising a third quantity of third nanostructures, the third quantity being different than the first quantity and the second quantity, the first cells, the second cells, and the third cells being interleaved in the repeating sequence along the direction of the device layout.

15. The method of claim 10, wherein a first length of the first cells is the same as a second length of the second cells.

16. The method of claim 10, wherein a first length of the first cells is different than a second length of the second cells.

17. A device comprising:
a first inverter comprising:
a first p-type transistor comprising first nanostructures, the first nanostructures having a first width; and
a first n-type transistor comprising second nanostructures, the second nanostructures having a second width, the second width different than the first width; and
a second inverter comprising:
a second p-type transistor comprising third nanostructures, the third nanostructures having a third width, the third width different than the first width; and
a second n-type transistor comprising fourth nanostructures, the fourth nanostructures having a fourth width, the fourth width different than the third width and the second width.

18. The device of claim 17, wherein the second width is greater than the first width.

19. The device of claim 17, wherein the fourth width is greater than the third width.

20. The device of claim 17, wherein the fourth width is less than the first width.
